(19) United States
(12) Patent Application Publication
(10) Pub. No.: US 2026/0305120 A1
(43) Pub. Date: Oct. 1, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: Won Sang PARK, Yongin-si (KR)

(21) Appl. No.: 19/558,907

(22) Filed: Mar. 6, 2026

(30) Foreign Application Priority Data
Mar. 27, 2025 (KR) 10-2025-0039293

(51) Int. Cl. H10K 59/80; H10K 39/34

(52) U.S. Cl. CPC H10K 59/80515; H10K 39/34

(57) ABSTRACT

A display device includes first to third display areas, a substrate and a circuit layer. A first pixel circuit is in the first display area, and second and third pixel circuits and a first sensor circuit is in the second display area. A first pixel electrode is in the first display area, a second pixel electrode is in the second display area, a third pixel electrode is in the third display area, and a first sensor electrode is in the second display area. The third pixel circuit is connected to the third pixel electrode by a second connection electrode extending from the second display area to the third display area. The first sensor circuit is connected to the first sensor electrode by a third connection electrode located in the second display area.

### CROSS-REFERENCE TO RELATED APPLICATION

This application claims priority under 35 U.S.C. §119 to Korean Patent Application No. 10-2025-0039293, filed on Mar. 27, 2025 in the Korean Intellectual Property Office, the disclosure of which is incorporated by reference in its entirety herein.

### 1. TECHNICAL FIELD

The present disclosure relates to a display device and an electronic device including the same.

### 2. DISCUSSION OF RELATED ART

The demands placed on display devices for displaying images in various ways has increased along with the advancement of the information-oriented society. For example, display devices are applied in an increasing variety of electronic devices, such as smartphones, digital cameras, laptop computers, navigation devices, and smart televisions.

The display device may include various optical devices such as an image sensor for capturing an image of the front surface, a proximity sensor for detecting whether a user or object is positioned close to the front surface of the display device, an illuminance sensor for detecting illumination of the front surface of the display device, and an iris sensor for recognizing an iris of a user.

Display devices are being provided in an increasing variety of designs along with the diversification of electronic devices employing display devices. For example, in the case of a smartphone, a display device may not include a hole located on the front surface of the display device to widen the display area. In this case, optical devices located in a hole located on the front surface of the display device may be located to overlap the display panel.

### SUMMARY

Aspects of the present disclosure provide a display device in which a sensor is embedded and an electronic device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, there is provided a display device including, a first display area, a second display area surrounded by the first display area, a third display area surrounded by the second display area, a substrate, a circuit layer located on the substrate, and including a first pixel circuit located in the first display area, and a second pixel circuit, a third pixel circuit, and a first sensor circuit located in the second display area, and an element layer located on the circuit layer. The element layer includes a first pixel electrode located in the first display area, a second pixel electrode located in the second display area, a third pixel electrode located in the third display area, and a first sensor electrode located in the second display area, a light emitting layer located on the first pixel electrode, the second pixel electrode, and the third pixel electrode, a light receiving layer located on the first sensor electrode, and a common electrode located on the light emitting layer and the light receiving layer. The second pixel circuit is connected to the second pixel electrode by a first connection electrode located in the second display area, the third pixel circuit is connected to the third pixel electrode by a second connection electrode extending from the second display area to the third display area, and the first sensor circuit is connected to the first sensor electrode by a third connection electrode located in the second display area.

In an embodiment, the second pixel electrode comprises a first sub-pixel electrode and a first copy pixel electrode, the first sub-pixel electrode and the first copy pixel electrode are connected by a first bridge portion, and the first sub-pixel electrode, the first copy pixel electrode, and the first bridge portion are an integrated electrode.

In an embodiment, the third pixel electrode comprises a second sub-pixel electrode and a second copy pixel electrode, the second sub-pixel electrode and the second copy pixel electrode are connected by a first connection pattern, and the first connection pattern is a separate electrode from the second sub-pixel electrode and the second copy pixel electrode.

In an embodiment, the second connection electrode comprises a transparent electrode.

In an embodiment, the first sensor electrode comprises a first sub-sensor electrode and a first copy sensor electrode, the first sub-sensor electrode and the first copy sensor electrode are connected by a first sensor bridge portion, and the first sub-sensor electrode, the first copy sensor electrode, and the first sensor bridge portion are an integrated electrode.

In an embodiment, the circuit layer further comprises a second sensor circuit located in the second display area, the element layer further comprises a second sensor electrode located in the third display area, and the second sensor circuit is connected to the second sensor electrode by a fourth connection electrode extending from the second display area to the third display area.

In an embodiment, the second sensor electrode comprises a second sub-sensor electrode and a second copy sensor electrode, the second sub-sensor electrode and the second copy sensor electrode are connected by a second connection pattern, and the second connection pattern is a separate electrode from the second sub-sensor electrode and the second copy sensor electrode.

In an embodiment, the second sensor electrode and the fourth connection electrode comprise a transparent electrode.

In an embodiment, the second sensor electrode is located in a same layer as the fourth connection electrode.

In an embodiment, the second sensor electrode is an electrode integrated with the fourth connection electrode.

In an embodiment, the circuit layer further comprises a via layer located below the first sensor electrode, and the via layer is located between the first sensor electrode and the third connection electrode.

In an embodiment, the via layer does not overlap the second sensor electrode in a plan view.

In an embodiment, the second sensor electrode is positioned at a height lower than a height of the first sensor electrode.

In an embodiment, a density of the first pixel electrode in the first display area is greater than a density of the second pixel electrode in the second display area, and a density of the second pixel electrode in the second display area is greater than a density of the third pixel electrode in the third display area.

In an embodiment, the display device may further comprise, a non-display area located outside the first display area, a display driving circuit located in the non-display area, and a read-out line crossing the first display area, the second display area, and the non-display area. The first sensor circuit is connected to the display driving circuit through the read-out line.

In an embodiment, the display device may further comprise, a touch sensing layer located on the element layer.

In an embodiment, the display device may further comprise, a color filter layer located on the touch sensing layer.

According to an embodiment of the present disclosure, there is provided a display device including, a first display area, a second display area surrounded by the first display area, a third display area surrounded by the second display area, a substrate, a circuit layer located on the substrate, and including a first pixel circuit located in the first display area, and a second pixel circuit, a third pixel circuit, a first sensor circuit, and a photosensitive transistor located in the second display area, and an element layer located on the circuit layer. The element layer includes a first pixel electrode located in the first display area, a second pixel electrode located in the second display area, and a third pixel electrode located in the third display area, a light emitting layer located on the first pixel electrode, the second pixel electrode, and the third pixel electrode, and a common electrode located on the light emitting layer. The second pixel circuit is connected to the second pixel electrode by a first connection electrode located in the second display area, the third pixel circuit is connected to the third pixel electrode by a second connection electrode extending from the second display area to the third display area, and the first sensor circuit is connected to the photosensitive transistor by a third connection electrode located in the second display area.

In an embodiment, the circuit layer further comprises a first active layer in which a semiconductor region of the first to third pixel circuits is located, and a second active layer in which a semiconductor region of the first sensor circuit is located, and a semiconductor region of the photosensitive transistor is located in at least one of the first active layer or the second active layer.

According to an embodiment of the present disclosure, there is provided an electronic device including, a display device displaying an image, a processor providing an image processing signal to the display device, and a power module supplying power to the display device and the processor. The display device includes, a first display area, a second display area surrounded by the first display area, a third display area surrounded by the second display area, a substrate, a circuit layer located on the substrate, and including a first pixel circuit located in the first display area, and a second pixel circuit, a third pixel circuit, and a first sensor circuit located in the second display area, and an element layer located on the circuit layer. The element layer includes a first pixel electrode located in the first display area, a second pixel electrode located in the second display area, a third pixel electrode located in the third display area, and a first sensor electrode located in the second display area, a light emitting layer located on the first pixel electrode, the second pixel electrode, and the third pixel electrode, a light receiving layer located on the first sensor electrode, and a common electrode located on the light emitting layer and the light receiving layer. The second pixel circuit is connected to the second pixel electrode by a first connection electrode located in the second display area, the third pixel circuit is connected to the third pixel electrode by a second connection electrode extending from the second display area to the third display area, and the first sensor circuit is connected to the first sensor electrode by a third connection electrode located in the second display area.

According to a display device and an electronic device including the same according to an embodiment of the present disclosure, a sensor may be embedded.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to an embodiment;

FIG. 2 is a plan view illustrating a display device according to an embodiment;

FIG. 3 is a cross-sectional view of the display device taken along line X1-X1' of FIG. 2 according to an embodiment;

FIG. 4 is a plan view illustrating a light emitting pixel, a sensing pixel, various drivers, and various wires of a display device according to an embodiment;

FIG. 5 is a block diagram illustrating a light emitting pixel, a sensing pixel, various drivers, and various wires of a display device according to an embodiment;

FIG. 6 is a circuit diagram illustrating a light emitting pixel of a display device according to an embodiment;

FIG. 7 is a cross-sectional view illustrating a light emitting pixel of a display device according to an embodiment;

FIG. 8 is a circuit diagram of a sensing pixel of a display device according to an embodiment;

FIG. 9 is a cross-sectional view illustrating a sensing pixel of a display device according to an embodiment;

FIG. 10 is an enlarged view of area A of FIG. 2 according to an embodiment;

FIG. 11 is a plan view of the arrangement of pixel electrodes in the main display area of the display device according to an embodiment;

FIG. 12 is a plan view showing the arrangement of pixel electrodes and the arrangement of sensor electrodes in a sub-display area of a display device according to an embodiment;

FIG. 13 is a cross-sectional view showing light emitting elements in a sub-display area of a display device according to an embodiment;

FIG. 14 is a cross-sectional view showing light receiving elements in a sub-display area of a display device according to an embodiment;

FIG. 15 is a plan view illustrating a display area of a display device according to an embodiment;

FIG. 16 is a plan view showing the arrangement of pixel electrodes and the arrangement of sensor electrodes in the sub-display area of the display device according to an embodiment of FIG. 15;

FIG. 17 is a cross-sectional view showing light receiving elements in the sub-display area of the display device according to an embodiment of FIG. 15;

FIG. 18 is a cross-sectional view showing light receiving elements in a sub-display area of a display device according to an embodiment;

FIG. 19 is a cross-sectional view showing light emitting elements and light receiving elements in a sub-display area of a display device according to an embodiment;

FIG. 20 is a cross-sectional view showing light emitting elements and a light receiving element in a sub-display area of a display device according to an embodiment;

FIG. 21 is a block diagram of an electronic device according to an embodiment; and

FIG. 22 is schematic views of electronic devices according to various embodiments.

### DETAILED DESCRIPTION OF EMBODIMENTS

The invention will now be described more fully hereinafter with reference to the accompanying drawings, in which embodiments of the invention are shown. This invention may, however, be embodied in different forms and should not be construed as limited to embodiments set forth herein.

It will also be understood that when a layer is referred to as being "on" another layer or substrate, it can be directly on the other layer or substrate, or intervening layers may also be present. When a layer is referred to as being "directly on" another layer or substrate, no intervening layers may be present. The same reference numbers indicate the same components throughout the specification.

Hereinafter, embodiments of the present disclosure will be described in detail with reference to the accompanying drawings.

A display device that includes a main display area and a sub-display area including a first sub-display area and a second sub-display area. The second sub-display area has a transmission area having high transmittance with respect to incident light. The second sub-display area includes an optical sensor.

In the sub-display area, a sub-pixel circuit for light emitting elements in the second sub-display area and a sensor circuit for the optical sensor in the second sub-display area area may be located in the first sub-display area and connected thereto by bridge electrodes extending from the first sub-display area to the second sub-display area. Therefore, the area of the transmission area in the second sub-display area is increased and the second sub-display area has an increased transmittance.

The display device includes a light receiving element sensing light which is embedded in the sub-display area. Therefore, an optical sensor such as a proximity sensor or a gesture sensor does not need to be provided as a separate optical device under the sub-display area. Accordingly, the display device may have a reduced manufacturing cost and increased compactness.

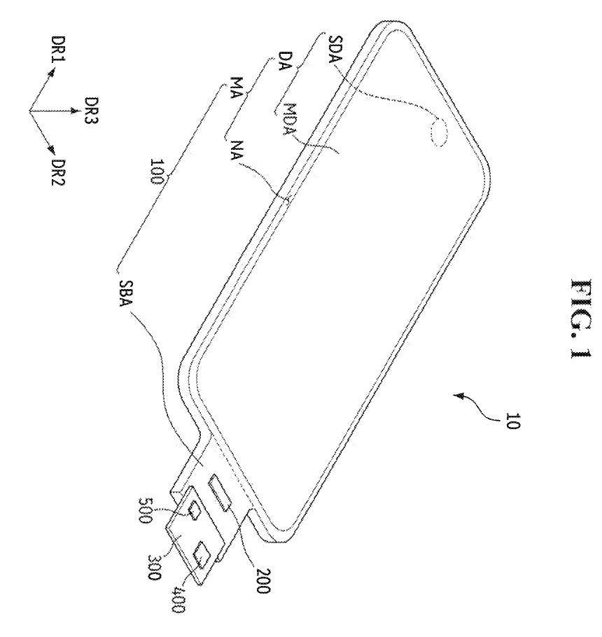

FIG. 1 is a perspective view showing a display device according to an embodiment.

Referring to FIG. 1, a display device 10, which is a device for displaying a moving image and/or a still image, may be used as a display screen of various small-sized, medium-sized and/or large-sized electronic devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook PC, an electronic book, a portable multimedia player (PMP), a navigation device and an ultra-mobile PC (UMPC).

The display device 10 may be a light emitting display device such as an organic light emitting display including an organic light emitting diode, a quantum dot light emitting display including a quantum dot light emitting layer, an inorganic light emitting display including an inorganic semiconductor, or a micro light emitting display using a micro or nano light emitting diode (LED). In the following, an embodiment in which the display device 10 is an organic light emitting display device is described, but the type of display device 10 is not necessarily limited thereto.

In an embodiment, the display device 10 may be formed flat. For example, the display device 10 may be formed substantially flat on a plane defined by a first direction DR1 and a second direction DR2, and may have a selected thickness (e.g., height) in a third direction DR3. In some embodiments, the display device 10 may include a curved surface in at least a part including an edge region and the like. In addition, the display device 10 may be formed to be flexible so that the display device can be curved, bent, folded, rolled or otherwise deformed.

In the illustrated figure, the first direction DR1 and the second direction DR2 cross each other as horizontal directions. For example, in an embodiment the first direction DR1 and the second direction DR2 may be orthogonal to each other. In addition, a third direction DR3 crosses the first direction DR1 and the second direction DR2, and may be, for example, perpendicular directions orthogonal to each other. However, embodiments of the present disclosure are not necessarily limited thereto and the first to third directions DR1 to DR3 may intersect each other in various different angles. Unless otherwise defined, in the present specification, directions indicated by arrows of the first to third directions DR1, DR2, and DR3 may be referred to as one side, and the opposite directions thereto may be referred to as the other side. Also, the terms "above," "upper side," "upper portion," "top," and "top surface," as used herein, refer to a direction indicated by an arrow in the drawing in the third direction DR3 based on the drawings, and the terms "below," "lower side," "lower portion," "bottom," and "bottom surface," as used herein, refer to a direction opposite to the direction indicated by the arrow in the third direction DR3 based on the drawings.

In an embodiment, with respect to the image display surface of the display device 10, the first direction DR1 may be a lengthwise direction, a column direction, or a vertical direction, and the second direction DR2 may be a direction intersecting the first direction DR1, for example, a widthwise direction, a row direction, or a horizontal direction. The third direction DR3 may be a thickness direction or a height direction of the display device 10.

In an embodiment, the display device 10 may include a display panel 100, a display driver 200, a circuit board 300, a touch driver 400, and a power supply unit 500.

The display panel 100 may include a main region MA including a display area DA in which an image is displayed, and a sub-region SBA located on one side of the main region MA.

The main region MA may include the display area DA and a non-display area NA surrounding the display area DA (e.g., in a plan view). The display area DA may be positioned in the center of the main region MA and occupy most of the area in the main region MA. The non-display area NA may be positioned at an edge of the main region MA and may be in direct contact with the sub-region SBA.

The display area DA may be an area in which pixels are arranged, and may be an area in which an image is displayed by pixels. In an embodiment, the display area DA may be further provided with sensing patterns (e.g., touch electrodes) for detecting a touch input and the like, and the display area DA may include a sensing area for detecting a touch input by the sensing patterns.

In an embodiment, the display area DA may include a long side in the first direction DR1 and a short side in the second direction DR2 and may be formed as a plane having an approximately rectangular shape. A corner portion at which the long side and the short side of the display area DA meet may be rounded or right-angled. The shape of the display area DA may be variously changed according to embodiments. For example, the display area DA may be formed in a polygonal shape other than a quadrilateral shape, a circular shape, an elliptical shape, or the like (e.g., in a plan view).

The display area DA may include a main display area MDA and a sub-display area SDA. The sub-display area SDA may be an area where components for adding various functions to the display device 10 are located, and the sub-display area SDA may correspond to a component area.

The non-display area NA may be located immediately around the display area DA (e.g., in a plan view). The non-display area NA may surround the display area DA (e.g., in a plan view). An embedded circuit may be located in the non-display area NA. For example, an embedded circuit including a scan driving circuit or the like may be located in the non-display area NA positioned on one side (e.g., the left side or the right side) or opposite sides of the display area DA.

The sub-region SBA may be located on one side of the main region MA. For example, in an embodiment the sub-region SBA may be a region protruding in a direction opposite to the first direction DR1 from one side of the main region MA, such as a lower side in a direction opposite to the first direction DR1. In an embodiment, the sub-region SBA may have a narrower width than the main region MA. For example, with respect to the second direction DR2, the sub-region SBA may have a narrower width than the main region MA.

Wires and pads may be located in the sub-region SBA. For example, in the sub-region SBA, the wires and pads connected to the pixels and/or the embedded circuit positioned in the main region MA and to the display driver 200 and/or the circuit board 300 positioned in the sub-region SBA may be located. In describing embodiments, the term "connect" may include electrical connection and/or physical connection.

In an embodiment, the display driver 200 (e.g., the display driving circuit) may be mounted in the sub-region SBA. The circuit board 300 may be located on a part of the sub-region SBA.

The display driver 200 may include a data driving circuit to drive pixels. In an embodiment, the display driver 200 may be formed as an integrated circuit (IC) chip and located in the sub-region SBA. In some embodiments, the display driver 200 may be located on the circuit board 300 on the sub-region SBA or may be located on another circuit board connected to the display panel 100 through the circuit board 300.

The circuit board 300 may be located on a part of the sub-region SBA. For example, in an embodiment the circuit board 300 may be bonded on the pads positioned on a portion (e.g., a lower edge) of the sub-region SBA, and may supply or transmit power voltages and driving signals for driving the display panel 100 to the display panel 100. For example, the circuit board 300 may supply input image data (e.g., digital image data), driving signals including timing signals, and driving voltages to the display panel 100. In an embodiment, the circuit board 300 may be a flexible film such as a flexible printed circuit board (FPCB), a printed circuit board (PCB), or a chip on film (COF), but is not necessarily limited thereto.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a selected frequency. The touch driver 400 may calculate whether an input is made and input coordinates based on an amount of change in capacitance between the plurality of touch electrodes. The touch driver 400 may be formed as an integrated circuit (IC).

The power supply unit 500 may be located on the circuit board 300 to supply a power voltage to the display driver 200 and the display panel 100. The power supply unit 500 may generate a driving voltage to supply the driving voltage to a driving voltage line, and may generate a common voltage to supply the common voltage to a common electrode. For example, in an embodiment the driving voltage may be a high potential voltage for driving the light emitting element, and the common voltage may be a low potential voltage for driving the light emitting element. The power supply unit 500 may generate an initialization voltage to supply the initialization voltage to an initialization voltage line, generate a reference voltage to supply the reference voltage to a reference voltage line, generate a bias voltage to supply the bias voltage to a bias voltage line, and generate a reset voltage to supply the reset voltage to a reset voltage line.

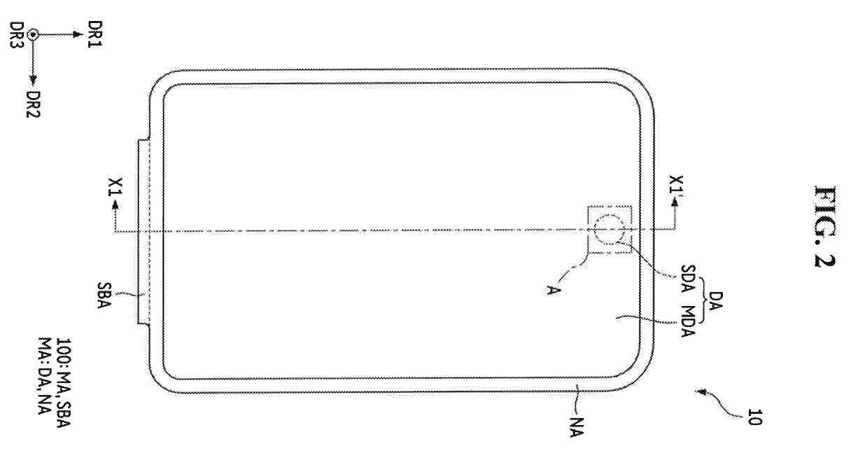

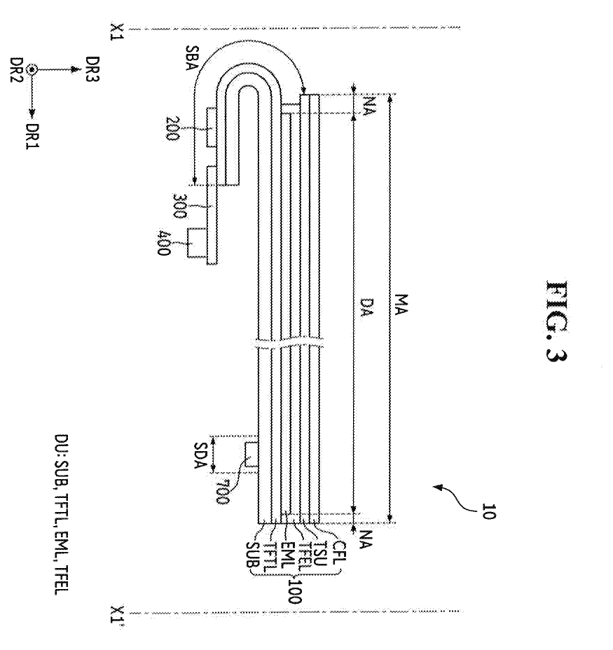

FIG. 2 is a plan view illustrating a display device according to an embodiment. FIG. 3 is a cross-sectional view of the display device taken along line X1-X1' of FIG. 2.

Referring to FIGS. 2 and 3, the display panel 100 may include a substrate SUB including the main region MA and the sub-region SBA, and a circuit layer TFTL, an element layer EML, an encapsulation layer TFEL, a touch sensing layer TSU, and a color filter layer CFL sequentially located on the substrate SUB. The circuit layer TFTL may also be positioned in the main region MA and the sub-region SBA on the substrate SUB. The element layer EML and the encapsulation layer TFEL may be positioned on a portion of the substrate SUB and the circuit layer TFTL. For example, the element layer EML and the encapsulation layer TFEL may be positioned in the main region MA.

In an embodiment, the display device 10 may further include an additional element located on the display panel 100. For example, the display device 10 may further include at least one of a polarization layer or a protective layer (e.g., a window) located on the encapsulation layer TFEL. Each of the polarization layer and/or the protective layer may be manufactured integrally with the display panel 100 or may be manufactured separately from the display panel 100 and attached to the display panel 100 through an adhesive layer or the like.

The substrate SUB may include an insulating material such as a polymer resin. For example, the substrate SUB may include polyimide or another insulating material. The substrate SUB may be a flexible substrate that can be transformed such as bending, folding, rolling or otherwise deformed. Alternatively, the substrate SUB may include an insulating material such as glass.

The circuit layer TFTL may include pixel circuits and wires. For example, the circuit layer TFTL may include circuit elements (e.g., pixel transistors and capacitors) constituting a pixel circuit for each pixel, and wires connected to the pixels. In an embodiment, the circuit layer TFTL may further include circuit elements constituting an embedded circuit, such as a scan driving circuit, and wires connected to the embedded circuit.

The element layer EML may include light emitting elements located in emission areas of the pixels. For example, each of the pixels may include at least one light emitting element and a pixel circuit connected to the light emitting element. Each of the pixels may be located in a pixel region, including the emission area where the light emitting element is located and a pixel circuit area where the pixel circuit is located. The emission area and the pixel circuit area of each pixel may overlap each other, but embodiments of the present disclosure are not necessarily limited thereto.

In describing embodiments, the circuit layer TFTL and the element layer EML are separately described, but embodiments of the present disclosure are not necessarily limited thereto. For example, the circuit layer TFTL and the element layer EML may be integrated with each other in some embodiments.

The encapsulation layer TFEL may cover the element layer EML and may extend to the non-display area NA to be in contact with the circuit layer TFTL. In an embodiment, the encapsulation layer TFEL may have a multilayer structure including at least two inorganic encapsulation layers overlapping each other and at least one organic encapsulation layer interposed between the inorganic encapsulation layers.

The touch sensing layer TSU may be located on the encapsulation layer TFEL (e.g., disposed directly thereon in the third direction DR3). The touch sensing layer TSU may include a plurality of touch electrodes for sensing a user's touch in a capacitive manner, and touch lines connecting the plurality of touch electrodes to the touch driver 400. For example, the touch sensing layer TSU may sense the user's touch by using a mutual capacitance method or a self-capacitance method.

In some embodiments, the touch sensing layer TSU may be located on a separate substrate located on the display panel 100. In this case, the substrate supporting the touch sensing layer TSU may be a base member that encapsulates the display panel 100.

The plurality of touch electrodes of the touch sensing layer TSU may be located in a touch sensor area overlapping the display area DA. The touch lines of the touch sensing layer TSU may be located in a touch peripheral area that overlaps the non-display area NA.

In some embodiments, the display device 10 may further include an optical device 700. The optical device 700 may be located in the sub-display area SDA. In an embodiment, the optical device 700 may emit or receive light in infrared, ultraviolet, and visible light bands. For example, the optical device 700 may be an optical sensor that detects light incident on the display device 10 such as a proximity sensor, an illuminance sensor, and a camera sensor or an image sensor.

The color filter layer CFL may be located on the touch sensing layer TSU (e.g., disposed directly thereon in the third direction DR3). The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a portion of light coming from the outside of the display device 10 to reduce reflected light due to external light. Accordingly, the color filter layer CFL may prevent color distortion caused by reflection of the external light.

Since the color filter layer CFL is directly located on the touch sensing layer TSU, the display device 10 may not require a separate substrate for the color filter layer CFL. Accordingly, the thickness of the display panel 100 may be relatively small.

In an embodiment, the display panel 100 may be bent in a bending area BA. The bending area BA may be a part of the sub-region SBA and may be spaced apart from the main region MA.

The substrate SUB and the circuit layer TFTL may be bent in the bending area BA corresponding to a partial section of the sub-region SBA. Accordingly, the bezel area recognized by a user as the non-display area NA may be reduced or minimized.

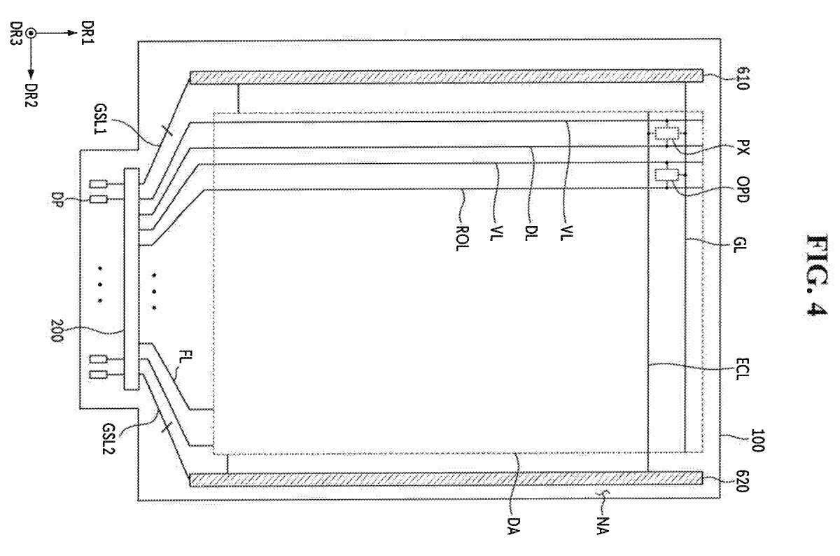

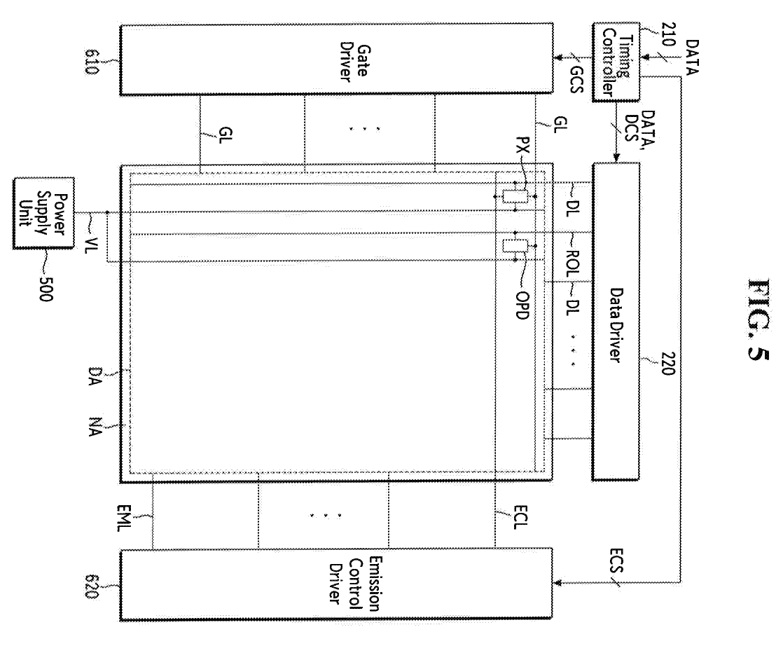

FIG. 4 is a plan view illustrating a light emitting pixel, a sensing pixel, various drivers, and various wires of a display device according to an embodiment. FIG. 5 is a block diagram illustrating a light emitting pixel, a sensing pixel, various drivers, and various wires of a display device according to an embodiment.

Referring to FIGS. 4 and 5, the display panel 100 may include the display area DA and the non-display area NA. In an embodiment, the display area DA may include a light emitting pixel PX, a sensing pixel OPD, a power line VL, a data line DL, a read-out line ROL, a gate line GL, and an emission control line ECL.

Each of the plurality of light emitting pixels PX may be connected to the gate line GL, the emission control line ECL, the data line DL, and the power line VL. Each of the light emitting pixels PX may include a plurality of transistors, a light emitting element, and a capacitor.

Each of the plurality of sensing pixels OPD may be connected to the gate line GL, the power line VL, and the read-out line ROL. Each of the plurality of sensing pixels OPD may include a plurality of transistors and a light receiving element.

In an embodiment, the gate lines GL may extend in the second direction DR2 and may be spaced apart from each other in the first direction DR1 intersecting the second direction DR2. The gate lines GL may sequentially supply a gate signal to the light emitting pixels PX and the sensing pixels OPD.

In an embodiment, the emission control lines ECL may extend in the second direction DR2 and may be spaced apart from each other in the first direction DR1. The emission control lines ECL may sequentially supply an emission signal to the plurality of light emitting pixels PX.

In an embodiment, the data lines DL may extend in the first direction DR1 and may be spaced apart from each other in the second direction DR2. The data lines DL may supply a data voltage to the plurality of light emitting pixels PX. The data voltage may determine the luminance of each of the light emitting pixels PX.

In an embodiment, the power lines VL may extend in the first direction DR1 and may be spaced apart from each other in the second direction DR2. The power line VL may supply a power voltage to the light emitting pixels PX and the sensing pixels OPD. In some embodiments, the power voltage may be a driving voltage, a common voltage, an initialization voltage, a reference voltage, a bias voltage, or a reset voltage. The driving voltage may be a high potential voltage for driving the light emitting pixel PX, and the common voltage may be a low potential voltage for driving the light emitting pixel PX and the sensing pixel OPD.

The non-display area NA may surround the display area DA (e.g., in a plan view). In an embodiment, the non-display area NA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the data line DL, supply the power voltage received from the display driver 200 to the power line VL, and supply the sensing signal received from the read-out line ROL to the display driver 200. Accordingly, the display driver 200 may drive the light emitting pixel SP and the sensing pixel OPD.

In some embodiments, the data line DL and the read-out line ROL may be located across the main display area MDA (see FIG. 1), the sub-display area SDA (see FIG. 1), and the non-display area NA (see FIG. 1).

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from one side of the non-display area NA (e.g., a side in a direction opposite to the first direction DR1). The sub-region SBA may include the display driver 200 and a pad portion DP. The pad portion DP may be located closer to one edge of the sub-region SBA than the display driver 200. In an embodiment, the pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may generate a data control signal DCS based on the timing signals, and may supply the digital video data DATA and the data control signal DCS to the data driver 220 to control the operation timing of the data driver 220. The timing controller 210 may generate the gate control signal GCS and supply the gate control signal to the gate driver 610, thus controlling the operation timing of the gate driver 610. The timing controller 210 may generate the emission control signal ECS and supply the emission control signal to the emission control driver 620, thus controlling the operation timing of the emission control driver 620.

In an embodiment, the data driver 220 may convert the digital video data DATA into analog data voltages and supply them to the data lines DL through the fan-out lines FL. The gate signals of the gate driver 610 may select the light emitting pixels PX to which the data voltage is supplied, and the selected light emitting pixels PX may receive the data voltage through the data lines DL. The data driver 220 may supply a sensing signal received through the read-out line ROL to the main processor.

The power supply unit 500 may be located on the circuit board 300 to supply a power voltage to the display driver 200 and the display panel 100. In an embodiment, the power supply unit 500 may generate a power voltage and supply the power voltage to the power line VL, and may generate a common voltage and supply the common voltage to the common electrode that is common to the light emitting pixels PX and the sensing pixels OPD. The power supply unit 500 may generate an initialization voltage to supply the initialization voltage to an initialization voltage line, generate a reference voltage to supply the reference voltage to a reference voltage line, generate a bias voltage to supply the bias voltage to a bias voltage line, and generate a reset voltage to supply the reset voltage to a reset voltage line.

The gate driver 610 may be located at one external side of the display area DA or at one side of the non-display area NA. The emission control driver 620 may be located at the other external side of the display area DA or at the other side of the non-display area NA. However, embodiments of the present disclosure are not necessarily limited thereto. As another example, the gate driver 610 and the emission control driver 620 may be located at any one of one side and the other side of the non-display area NA.

The gate driver 610 may include a plurality of transistors for generating gate signals based on the gate control signal GCS. The emission control driver 620 may include a plurality of transistors for generating emission signals based on the emission control signal ECS. For example, the transistors of the gate driver 610 and the transistors of the emission control driver 620 may be formed in the same layer as the transistors of each of the light emitting pixels PX. The gate driver 610 may supply the gate signals to the gate lines GL, and the emission control driver 620 may supply the emission signals to the emission control lines ECL.

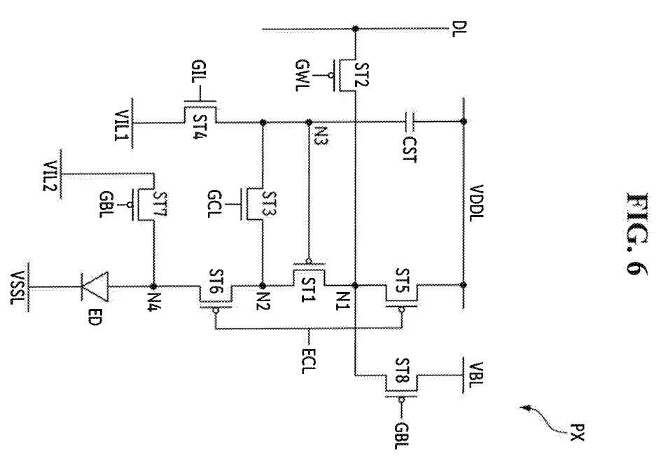

FIG. 6 is a circuit diagram illustrating a light emitting pixel of a display device according to an embodiment.

Referring to FIG. 6, the light emitting pixel PX may be connected to a first gate line GWL, a second gate line GCL, a third gate line GIL, a fourth gate line GBL, the emission control line ECL, the data line DL, a driving voltage line VDDL, a first initialization voltage line VIL1, a second initialization voltage line VIL2, a bias voltage line VBL, and a low potential line VSSL.

The light emitting pixel PX may include a light emitting element ED and a light emitting pixel circuit for driving the light emitting element ED. The light emitting pixel circuit may include first to eighth transistors ST1, ST2, ST3, ST4, ST5, ST6, ST7, and ST8 and a capacitor CST.

The first transistor ST1 may control a driving current supplied to the light emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. For example, in an embodiment the first electrode of the first transistor ST1 may be a source electrode and the second electrode thereof may be a drain electrode, but embodiments of the present disclosure are not necessarily limited thereto.

The first transistor ST1 may control a source-drain current (hereinafter, referred to as "driving current") according to the data voltage applied to the gate electrode. In an embodiment, the driving current flowing through the channel of the first transistor ST1 may be proportional to the square of a difference between a threshold voltage Vth and a voltage Vsg between the source electrode and the gate electrode of the first transistor ST1 (Isd = k × (Vsg – Vth)²). Here, k is a proportional coefficient determined by the structure and physical characteristics of the first transistor ST1, Vsg is a source-gate voltage of the first transistor ST1, and Vth is a threshold voltage of the first transistor ST1.

The light emitting element ED may emit light by receiving a driving current. The light emission amount or the luminance of the light emitting element ED may be proportional to the magnitude of the driving current. The light emitting element ED may include a first electrode, a second electrode, and a light emitting layer located between the first electrode and the second electrode. The first electrode of the light emitting element ED may be connected to a fourth node N4. The first electrode of the light emitting element ED may be connected to the second electrode of the sixth transistor ST6 and the first electrode of the seventh transistor ST7 through the fourth node N4. The second electrode of the light emitting element ED may be electrically connected to the low potential line VSSL. The second electrode of the light emitting element ED may receive the low potential voltage from the low potential line VSSL. For example, in an embodiment the first electrode of the light emitting element ED may be an anode electrode or a pixel electrode, and the second electrode thereof may be a cathode electrode or a common electrode, but embodiments of the present disclosure are not necessarily limited thereto.

The second transistor ST2 may be turned on by the first gate signal of the first gate line GWL to electrically connect the data line DL to the first node N1 which is the first electrode of the first transistor ST1. The second transistor ST2 may be turned on based on the first gate signal to supply the data voltage to the first node N1. The gate electrode of the second transistor ST2 may be connected to the first gate line GWL, the first electrode thereof may be connected to the data line DL, and the second electrode thereof may be connected to the first node N1. The second electrode of the second transistor ST2 may be connected to the first electrode of the first transistor ST1, the second electrode of the fifth transistor ST5, and the second electrode of the eighth transistor ST8 through the first node N1. For example, in an embodiment the first electrode of the second transistor ST2 may be a source electrode and the second electrode thereof may be a drain electrode, but embodiments of the present disclosure are not necessarily limited thereto.

The third transistor ST3 may be turned on by the second gate signal of the second gate line GCL to electrically connect the second node N2, which is the second electrode of the first transistor ST1, to the third node N3, which is the gate electrode the first transistor ST1. The gate electrode of the third transistor ST3 may be connected to the second gate line GCL, the first electrode thereof may be connected to the second node N2, and the second electrode thereof may be connected to the third node N3. The first electrode of the third transistor ST3 may be connected to the second electrode of the first transistor ST1 and the first electrode of the sixth transistor ST6 through the second node N2. The second electrode of the third transistor ST3 may be connected to the gate electrode of the first transistor ST1, the first electrode of the fourth transistor ST4, and a first capacitor electrode of the capacitor CST through the third node N3. For example, in an embodiment the first electrode of the third transistor ST3 may be a drain electrode and the second electrode thereof may be a source electrode, but embodiments of the present disclosure are not necessarily limited thereto.

The fourth transistor ST4 may be turned on by a third gate signal of the third gate line GIL to electrically connect the third node N3, which is the gate electrode of the first transistor ST1, to the first initialization voltage line VIL1. The fourth transistor ST4 may be turned on based on the third gate signal, thereby discharging the gate electrode of the first transistor ST1 to a first initialization voltage. The gate electrode of the fourth transistor ST4 may be connected to the third gate line GIL, the first electrode thereof may be connected to the third node N3, and the second electrode thereof may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. For example, in an embodiment the first electrode of the fourth transistor ST4 may be a drain electrode and the second electrode thereof may be a source electrode, but embodiments of the present disclosure are not necessarily limited thereto.

The fifth transistor ST5 may be turned on by an emission signal of the emission control line ECL to electrically connect the driving voltage line VDDL with the first node N1 that is the first electrode of the first transistor ST1. The gate electrode of the fifth transistor ST5 may be connected to the emission control line ECL, the first electrode thereof may be connected to the driving voltage line VDDL, and the second electrode thereof may be connected to the first node N1. The second electrode of the fifth transistor ST5 may be electrically connected to the first electrode of the first transistor ST1, the second electrode of the second transistor ST2, and the second electrode of the eighth transistor ST8 through the first node N1. For example, in an embodiment the first electrode of the fifth transistor ST5 may be a source electrode and the second electrode thereof may be a drain electrode, but embodiments of the present disclosure are not necessarily limited thereto.

The sixth transistor ST6 may be turned on by the emission signal of the emission control line ECL to electrically connect the second node N2 that is the second electrode of the first transistor ST1 with the fourth node N4 that is the first electrode of the light emitting element ED. The gate electrode of the sixth transistor ST6 may be connected to the emission control line ECL, the first electrode thereof may be connected to the second node N2, and the second electrode thereof may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light emitting element ED and the first electrode of the seventh transistor ST7 through the fourth node N4. For example, in an embodiment the first electrode of the sixth transistor ST6 may be a source electrode and the second electrode thereof may be a drain electrode, but embodiments of the present disclosure are not necessarily limited thereto.

When all of the fifth transistor ST5, the first transistor ST1, and the sixth transistor ST6 are turned on, the driving current may be supplied to the light emitting element ED.

The seventh transistor ST7 may be turned on by the fourth gate signal of the fourth gate line GBL to electrically connect the second initialization voltage line VIL2 to the fourth node N4, which is the first electrode of the light emitting element ED. By turning on the seventh transistor ST7 based on the fourth gate signal, the first electrode of the light emitting element ED may be discharged to a second initialization voltage. The gate electrode of the seventh transistor ST7 may be connected to the fourth gate line GBL, the first electrode thereof may be connected to the fourth node N4, and the second electrode thereof may be connected to the second initialization voltage line VIL2. The first electrode of the seventh transistor ST7 may be connected to the first electrode of the light emitting element ED and the second electrode of the sixth transistor ST6 through the fourth node N4. For example, in an embodiment the first electrode of the seventh transistor ST7 may be a source electrode and the second electrode thereof may be a drain electrode, but embodiments of the present disclosure are not necessarily limited thereto.

The eighth transistor ST8 may be turned on by the fourth gate signal of the fourth gate line GBL to electrically connect the bias voltage line VBL with the first node N1 that is the first electrode of the first transistor ST1. The gate electrode of the eighth transistor ST8 may be connected to the fourth gate line GBL, the first electrode thereof may be connected to the bias voltage line VBL, and the second electrode thereof may be connected to the first node N1. The second electrode of the eighth transistor ST8 may be electrically connected to the first electrode of the first transistor ST1, the second electrode of the second transistor ST2, and the second electrode of the fifth transistor ST5 through the first node N1. For example, in an embodiment the first electrode of the eighth transistor ST8 may be a source electrode and the second electrode thereof may be a drain electrode, but embodiments of the present disclosure are not necessarily limited thereto. In some embodiments, the eighth transistor ST8 may be omitted.

Each of the first transistor ST1, the second transistor ST2, the fifth transistor ST5, the sixth transistor ST6, the seventh transistor ST7, and the eighth transistor ST8 may include a silicon-based semiconductor region. For example, in an embodiment each of the first transistor ST1, the second transistor ST2, the fifth transistor ST5, the sixth transistor ST6, the seventh transistor ST7, and the eighth transistor ST8 may include a semiconductor region containing low temperature polycrystalline silicon (LTPS). The semiconductor region containing low temperature polycrystalline silicon may have high electron mobility and excellent turn-on characteristics. Accordingly, since the display device 10 includes the first transistor ST1, the second transistor ST2, the fifth transistor ST5, the sixth transistor ST6, the seventh transistor ST7, and the eighth transistor ST8 having excellent turn-on characteristics, the plurality of light emitting pixels PX can be driven stably and efficiently.

In an embodiment, each of the first, second, fifth, sixth, seventh, and eighth transistors ST1, ST2, ST5, ST6, ST7, and ST8 may correspond to a p-type transistor. For example, each of the first transistor ST1, the second transistor ST2, the fifth transistor ST5, the sixth transistor ST6, the seventh transistor ST7, and the eighth transistor ST8 may output a current flowing into the first electrode to the second electrode based on a gate low voltage applied to the gate electrode.

Each of the third transistor ST3 and the fourth transistor ST4 may include an oxide-based semiconductor region. For example, each of the third transistor ST3 and the fourth transistor ST4 may have a coplanar structure in which the gate electrode is located on the oxide-based semiconductor region. The transistor having the coplanar structure may have excellent leakage current characteristics and perform low frequency driving, thereby reducing power consumption. Accordingly, the display device 10 may include the third transistor ST3 and the fourth transistor ST4 having excellent leakage current characteristics, thereby preventing a leakage current from flowing in the light emitting pixel, and stably maintaining the voltage in the light emitting pixel.

In an embodiment, each of the third transistor ST3 and the fourth transistor ST4 may correspond to an n-type transistor. For example, each of the third transistor ST3 and the fourth transistor ST4 may output a current flowing into the first electrode to the second electrode based on a gate high voltage applied to the gate electrode.

The capacitor CST may be connected between the third node N3, which is the gate electrode of the first transistor ST1, and the driving voltage line VDDL. For example, the first capacitor electrode of the capacitor CST may be connected to the third node N3, and the second capacitor electrode of the capacitor CST may be connected to the driving voltage line VDDL, thereby maintaining a potential difference between the driving voltage line VDDL and the gate electrode of the first transistor ST1.

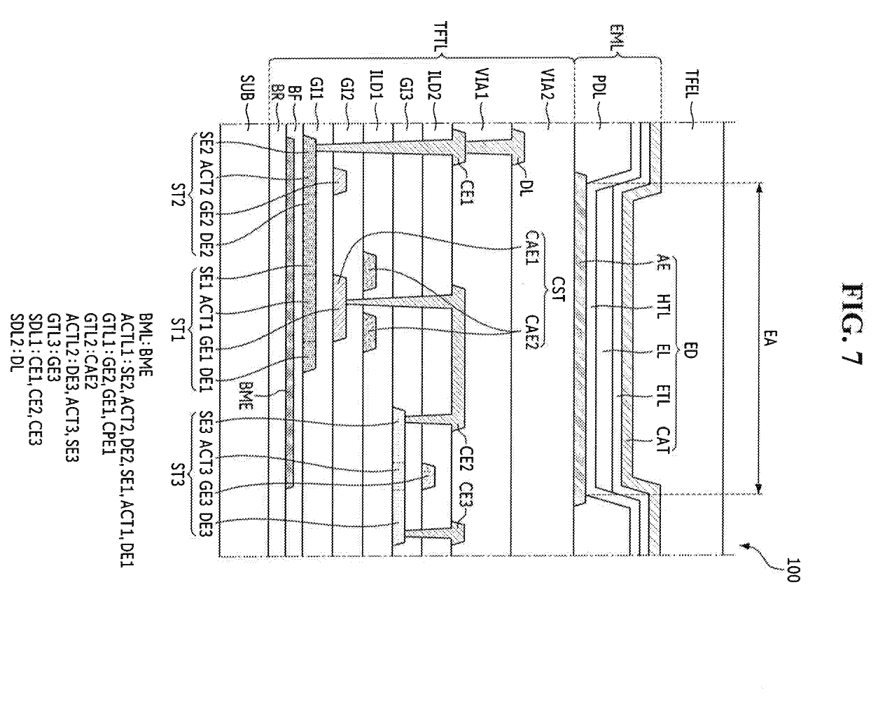

FIG. 7 is a cross-sectional view illustrating a light emitting pixel of a display device according to an embodiment.

Referring to FIG. 7 in addition to FIG. 6, in an embodiment the display panel 100 may include the substrate SUB, the transistor layer TFTL, the element layer EML, and the encapsulation layer TFEL. The light emitting pixel PX may include the light emitting pixel circuit and the light emitting element ED. The light emitting pixel circuit may be located in the transistor layer TFTL, and the light emitting element ED may be located in the element layer EML.

The substrate SUB may be a base substrate or a base member. In an embodiment, the substrate SUB may be a flexible substrate which can be bent, folded, rolled or otherwise deformed. For example, in an embodiment the substrate SUB may include a polymer resin such as polyimide, but embodiments of the present disclosure are not necessarily limited thereto. For another example, the substrate SUB may include a glass material or a metal material and may not be flexible.

In an embodiment, the transistor layer TFTL may include a barrier layer BR, a lower conductive layer BML, a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The barrier layer BR may be located on the substrate SUB (e.g., disposed directly thereon in the third direction DR3). For example, the barrier layer BR may be located on the entire surface of the substrate SUB. The barrier layer BR may be a film for protecting transistors of the transistor layer TFTL and a light emitting layer EL of the element layer EML from moisture permeating through the substrate SUB which is susceptible to moisture permeation. In an embodiment, the barrier layer BR may include a plurality of inorganic films that are alternately stacked (e.g., in the third direction DR3). For example, in an embodiment the barrier layer BR may be a single film or multiple films in which one or more inorganic films of a silicon nitride layer, a silicon oxynitride layer, a silicon oxide layer, a titanium oxide layer and an aluminum oxide layer are alternately stacked.

The lower conductive layer BML may be located on the barrier layer BR (e.g., disposed directly thereon in the third direction DR3). In an embodiment, the lower conductive layer BML may include a lower conductive pattern BME that overlaps the semiconductor regions ACT1 and ACT2 of the first transistor ST1 and the second transistor ST2 in the third direction DR3 to prevent leakage current from occurring due to light incident on the first active layer ACTL1. In an embodiment, the lower conductive layer BML may be formed as a single layer or multiple layers including any one of molybdenum (Mo), aluminum (Al), chromium (Cr), gold (Au), titanium (Ti), nickel (Ni), neodymium (Nd) and copper (Cu) or an alloy thereof. In some embodiments, the lower conductive layer BML may be omitted.

The buffer layer BF may be located on (e.g., disposed directly thereon) the lower conductive layer BML. The buffer layer BF may include an inorganic layer capable of preventing permeation of air or moisture. The buffer layer BF may include a plurality of inorganic layers that are alternately stacked (e.g., in the third direction DR3). For example, in an embodiment the buffer layer BF may be a single film or multiple films in which one or more inorganic films of a silicon nitride layer, a silicon oxynitride layer, a silicon oxide layer, a titanium oxide layer and an aluminum oxide layer are alternately stacked (e.g., in the third direction DR3).

The first active layer ACTL1 may be located on the buffer layer BF (e.g., disposed directly thereon in the third direction DR3). The first active layer ACTL1 may include a silicon-based material. For example, in an embodiment the first active layer ACTL1 may include low temperature polycrystalline silicon (LTPS). The first active layer ACTL1 may include the semiconductor region ACT1, the first electrode SE1, and the second electrode DE1 of the first transistor ST1, and the semiconductor region ACT2, the first electrode SE2, and the second electrode DE2 of the second transistor ST2.

The first gate insulating layer GI1 may be located on (e.g., disposed directly thereon) the first active layer ACTL1. The first gate insulating layer GI1 may insulate the first active layer ACTL1 from the first gate layer GTL1.

The first gate layer GTL1 may be located on the first gate insulating layer GI1 (e.g., disposed directly thereon in the third direction DR3). The first gate layer GTL1 may include the gate electrode GE1 of the first transistor ST1, the gate electrode GE2 of the second transistor ST2, and the first capacitor electrode CAE1. The gate electrode GE1 of the first transistor ST1 may be a part of the first capacitor electrode CAE1, and the gate electrode GE2 of the second transistor ST2 may be a part of the first gate line GWL.

The second gate insulating layer GI2 may be located on (e.g., disposed directly thereon) the first gate layer GTL1. The second gate insulating layer GI2 may insulate the first gate layer GTL1 from the second gate layer GTL2.

The second gate layer GTL2 may be located on the second gate insulating layer GI2 (e.g., disposed directly thereon in the third direction DR3). The second gate layer GTL2 may include a second capacitor electrode CAE2. The second capacitor electrode CAE2 may overlap the first capacitor electrode CAE1.

The first interlayer insulating layer ILD1 may be located on (e.g., disposed directly thereon) the second gate layer GTL2. The first interlayer insulating layer ILD1 may insulate the second gate layer GTL2 from the second active layer ACTL2.

The second active layer ACTL2 may be located on the first interlayer insulating layer ILD1 (e.g., disposed directly thereon in the third direction DR3). In an embodiment the second active layer ACTL2 may include an oxide-based material. The second active layer ACTL2 may include the semiconductor region ACT3, the first electrode DE3, and the second electrode SE3 of the third transistor ST3.

The third gate insulating layer GI3 may be located on (e.g., disposed directly thereon) the second active layer ACTL2. The third gate insulating layer GI3 may insulate the second active layer ACTL2 from the third gate layer GTL3.

The third gate layer GTL3 may be located on the third gate insulating layer GI3 (e.g., disposed directly thereon in the third direction DR3). The third gate layer GTL3 may include a gate electrode GE3 of the third transistor ST3. The gate electrode GE3 of the third transistor ST3 may be a part of the second gate line GCL.

The second interlayer insulating layer ILD2 may be located on (e.g., disposed directly thereon) the third gate layer GTL3. The second interlayer insulating layer ILD2 may insulate the third gate layer GTL3 from the first source metal layer SDL1.

The first source metal layer SDL1 may be located on the second interlayer insulating layer ILD2 (e.g., disposed directly thereon in the third direction DR3). The first source metal layer SDL1 may include first to third connection electrodes CE1, CE2, and CE3. The first connection electrode CE1 may electrically connect the data line DL to the first electrode SE2 of the second transistor ST2. The second connection electrode CE2 may electrically connect the first capacitor electrode CAE1 to the second electrode SE3 of the third transistor ST3. The third connection electrode CE3 may electrically connect the first electrode DE3 of the third transistor ST3 to the second electrode DE1 of the first transistor ST1.

The first via layer VIA1 may be located on (e.g., disposed directly thereon) the first source metal layer SDL1. The first via layer VIA1 may insulate the first source metal layer SDL1 from the second source metal layer SDL2. The top surface of the first via layer VIA1 may be flat. In an embodiment, the first via layer VIA1 may contain an organic insulating material such as polyimide (PI).

The second source metal layer SDL2 may be located on the first via layer VIA1 (e.g., disposed directly thereon in the third direction DR3). The second source metal layer SDL2 may include the data line DL.

The second via layer VIA2 may be located on (e.g., disposed directly thereon) the second source metal layer SDL2. The second via layer VIA2 may insulate the second source metal layer SDL2 from a pixel electrode AE. The top surface of the second via layer VIA2 may be flat. In an embodiment, the second via layer VIA2 may contain an organic insulating material such as polyimide (PI).

The element layer EML may include a pixel defining film PDL and the light emitting element ED.

The pixel defining film PDL may be located on the second via layer VIA2 (e.g., disposed directly thereon in the third direction DR3). The pixel defining film PDL may define a plurality of emission areas EA. In an embodiment, the pixel defining film PDL may include an organic insulating material such as polyimide (PI), but embodiments of the present disclosure are not necessarily limited thereto.

The light emitting element ED may include the pixel electrode AE, the hole transporting layer HTL, the light emitting layer EL, the electron transporting layer ETL, and the common electrode CAT. The pixel electrode AE may be located on the second via layer VIA2 (e.g., disposed directly thereon in the third direction DR3). The pixel electrode AE may overlap one of the plurality of emission areas EA defined by the pixel defining film PDL. The pixel electrode AE may receive a driving current from the pixel circuit of the light emitting pixel PX.

The hole transporting layer HTL may be located on (e.g., disposed directly thereon in the third direction DR3) the pixel electrode AE in the emission area EA and may be located on (e.g., disposed directly thereon in the third direction DR3) the pixel defining film PDL in an area other than the emission area EA. In an embodiment, the hole transporting layer HTL may be implemented as a common layer for all the light emitting pixels PX and the sensing pixels OPD, rather than being divided for each light emitting pixel PX.

The light emitting layer EL may be located on (e.g., disposed directly thereon) the hole transporting layer HTL in the emission area EA. For example, the light emitting layer EL may be an organic light emitting layer including an organic material, but embodiments of the present disclosure are not necessarily limited thereto.

The electron transporting layer ETL may be located on (e.g., disposed directly thereon in the third direction DR3) the light emitting layer EL in the emission area EA and may be located on (e.g., disposed directly thereon) the hole transporting layer HTL in an area other than the emission area EA. In an embodiment, the electron transporting layer ETL may be implemented as a common layer for all the light emitting pixels PX and the sensing pixels OPD, rather than being divided for each light emitting pixel PX.

The common electrode CAT may be located on (e.g., disposed directly thereon) the electron transporting layer ETL. For example, the common electrode CAT may be implemented in the form of an electrode that is common to all the light emitting pixels PX and the sensing pixels OPD, rather than being divided for each of the plurality of light emitting pixels PX. The common electrode CAT may be a transparent electrode and may transmit light. The common electrode CAT may be electrically connected to the low potential line VSSL and may receive a low potential voltage, a common voltage, or a cathode voltage.

In the case where the light emitting layer EL corresponds to an organic light emitting layer, when a selected voltage is applied to the pixel electrode AE in the pixel circuit of the light emitting pixel PX, and the common electrode CAT receives a common voltage or a cathode voltage, holes may move to the light emitting layer EL through the hole transporting layer HTL, electrons may move to the light emitting layer EL through the electron transporting layer ETL, and the holes and the electrons may combine with each other in the light emitting layer EL to emit light.

The encapsulation layer TFEL may be located on (e.g., disposed directly thereon) the common electrode CAT to cover the plurality of light emitting elements ED. The encapsulation layer TFEL may include at least one inorganic film to prevent oxygen or moisture from permeating into the plurality of light emitting elements ED. The encapsulation layer TFEL may include at least one organic film to protect the plurality of light emitting elements ED from foreign matters such as dust.

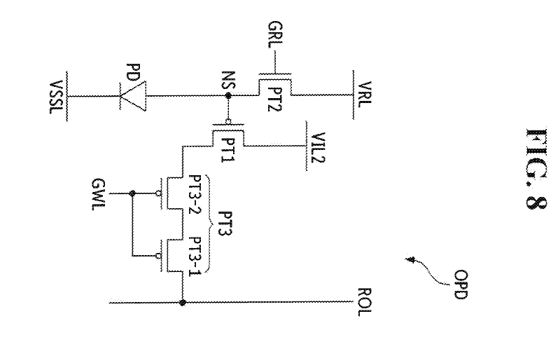

FIG. 8 is a circuit diagram of a sensing pixel of a display device according to an embodiment.

Referring to FIG. 8, the sensing pixel OPD may be connected to the first gate line GWL, the reset signal line GRL, the reset voltage line VRL, the second initialization voltage line VIL2, the low potential line VSSL, and the read-out line ROL.

The sensing pixel OPD may include a light receiving element PD and a sensing pixel circuit for driving the light receiving element PD. In an embodiment, the sensing pixel circuit may include first to third sensor transistors PT1, PT2, and PT3.

The first sensor transistor PT1 may include a gate electrode, a first electrode, and a second electrode. The gate electrode of the first sensor transistor PT1 may be connected to the sensor node NS, the first electrode thereof may be connected to the third sensor transistor PT3, and the second electrode thereof may be connected to the second initialization voltage line VIL2. The first sensor transistor PT1 may control the source-drain current (hereinafter referred to as "sensing current") based on the voltage of the sensor node NS, which is the first electrode of the light receiving element PD. In an embodiment, the sensing current flowing through the channel of the first sensor transistor PT1 may be proportional to the square of a difference between the threshold voltage Vth and the voltage Vsg between the source electrode and the gate electrode of the first sensor transistor PT1 (Isd = k' × (Vsg – Vth)²). Here, k' is a proportional coefficient determined by the structure and physical characteristics of the first sensor transistor PT1, Vsg is a source-gate voltage of the first sensor transistor PT1, and Vth is a threshold voltage of the first sensor transistor PT1. In an embodiment, the first electrode of the first sensor transistor PT1 may be a source electrode and the second electrode thereof may be a drain electrode, but embodiments of the present disclosure are not necessarily limited thereto.

The second sensor transistor PT2 may be turned on by the reset signal of the reset signal line GRL, thereby discharging the voltage of the sensor node NS to the reset voltage. The gate electrode of the second sensor transistor PT2 may be connected to the reset signal line GRL, the first electrode thereof may be connected to the sensor node NS, and the second electrode thereof may be connected to the reset voltage line VRL. The first electrode of the second sensor transistor PT2 may be connected to the first electrode of the light receiving element PD and the gate electrode of the first sensor transistor PT1 through the sensor node NS. In an embodiment, the first electrode of the second sensor transistor PT2 may be a drain electrode and the second electrode thereof may be a source electrode, but embodiments of the present disclosure are not necessarily limited thereto.

The third sensor transistor PT3 may be turned on by the first gate signal of the first gate line GWL to electrically connect the first electrode of the first sensor transistor PT1 to the read-out line ROL. In an embodiment, the third sensor transistor PT3 may include a third-first sensor transistor PT3-1 and a third-second sensor transistor PT3-2 connected in series. The third-first sensor transistor PT3-1 and the third-second sensor transistor PT3-2 may be connected in series between the first electrode of the first sensor transistor PT1 and the read-out line ROL. The gate electrode of the third-first sensor transistor PT3-1 and the gate electrode of the third-second sensor transistor PT3-2 may be integrally formed and electrically connected to the first gate line GWL. The first electrode of the third-first sensor transistor PT3-1 may be connected to the read-out line ROL, and the second electrode of the third-second sensor transistor PT3-2 may be connected to the first electrode of the first sensor transistor PT1. The second electrode of the third-first sensor transistor PT3-1 and the first electrode of the third-second sensor transistor PT3-2 may be integrally formed. In an embodiment, the first electrode of each of the third-first sensor transistor PT3-1 and the third-second sensor transistor PT3-2 may be a source electrode and the second electrode thereof may be a drain electrode, but embodiments of the present disclosure are not necessarily limited thereto.

The light receiving element PD may receive light and convert light energy into an electrical signal. The first electrode of the light receiving element PD may be connected to the sensor node NS, which is the gate electrode of the first sensor transistor PT1, and the second electrode thereof may be connected to the low potential line VSSL. The second electrode of the light receiving element PD may receive the low potential voltage from the low potential line VSSL. For example, in an embodiment the first electrode of the light receiving element PD may be a sensor electrode, and the second electrode thereof may be a common electrode, but embodiments of the present disclosure are not necessarily limited thereto.

When the object is positioned above the display panel 100, light emitted from the light emitting element may be reflected by the object, and the light receiving element PD may receive the reflected light. The light receiving element PD may convert the energy of light into an electrical signal (e.g., current or voltage) formed between the first and second electrodes, and the converted electrical signal may flow from the low potential line VSSL to the sensor node NS as a reverse bias current. For example, when the light receiving element PD receives light and an electric field is formed between the first and second electrodes of the light receiving element PD, a current may flow through the light receiving element PD in proportion to the amount of light and the voltage at the sensor node NS may increase. Accordingly, when the light receiving element PD receives light, the voltage of the sensor node NS may increase and the magnitude of a sensing current (e.g., source-drain current) of the first sensor transistor PT1 may decrease. The sensing current of the first sensor transistor PT1 may be applied to the display driver 200 as a sensing signal through the third sensor transistor PT3 and the read-out line ROL.

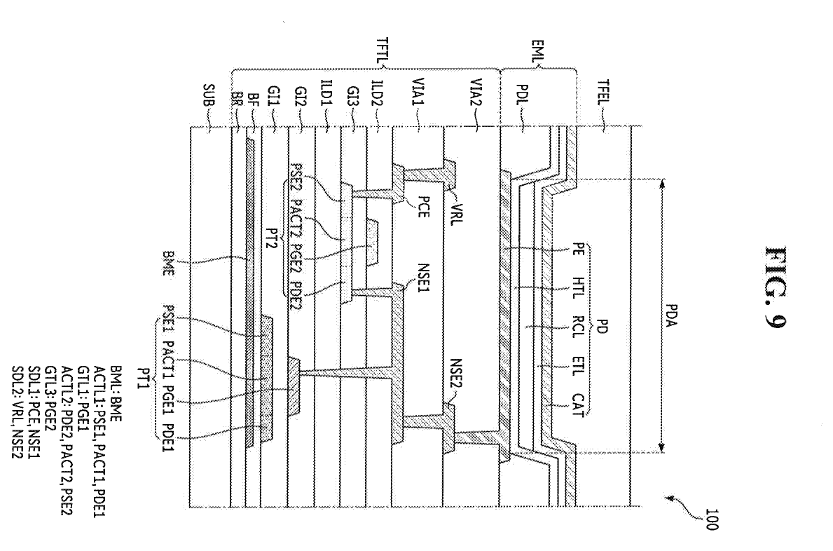

FIG. 9 is a cross-sectional view illustrating a sensing pixel of a display device according to an embodiment.

Referring to FIG. 9 in addition to FIG. 8, in an embodiment the display panel 100 may include the substrate SUB, the transistor layer TFTL, the element layer EML, and the encapsulation layer TFEL. The sensing pixel OPD may include the sensing pixel circuit and the light receiving element PD. The sensing pixel circuit may be located in the transistor layer TFTL, and the light receiving element PD may be located in the element layer EML.

Descriptions of the substrate SUB and the encapsulation layer TFEL have been previously provided with reference to FIG. 7 and are therefore omitted here for economy of explanation.

In an embodiment, the transistor layer TFTL may include the barrier layer BR, the lower conductive layer BML, the buffer layer BF, the first active layer ACTL1, the first gate insulating layer GI1, the first gate layer GTL1, the second gate insulating layer GI2, the first interlayer insulating layer ILD1, the second active layer ACTL2, the third gate insulating layer GI3, the third gate layer GTL3, the second interlayer insulating layer ILD2, the first source metal layer SDL1, the first via layer VIA1, the second source metal layer SDL2, and the second via layer VIA2.

Descriptions of the barrier layer BR, the lower conductive layer BML, the buffer layer BF, the first gate insulating layer GI1, the second gate insulating layer GI2, the first interlayer insulating layer ILD1, the third gate insulating layer GI3, the second interlayer insulating layer ILD2, the first via layer VIA1, and the second via layer VIA2 of the transistor layer TFTL have been previously provided with reference to FIG. 7 and are therefore omitted here for economy of explanation.

The first active layer ACTL1 may be located on the buffer layer BF (e.g., disposed directly thereon in the third direction DR3). The first active layer ACTL1 may include a silicon-based material. For example, in an embodiment the first active layer ACTL1 may include low temperature polycrystalline silicon (LTPS). The first active layer ACTL1 may include a semiconductor region PACT1, a first electrode PSE1, and a second electrode PDE1 of the first sensor transistor PT1.

The first gate layer GTL1 may be located on the first gate insulating layer GI1 (e.g., disposed directly thereon in the third direction DR3). The first gate layer GTL1 may include a gate electrode PGE1 of the first sensor transistor PT1.

The second active layer ACTL2 may be located on the first interlayer insulating layer ILD1 (e.g., disposed directly thereon in the third direction DR3). In an embodiment, the second active layer ACTL2 may include an oxide-based material. The second active layer ACTL2 may include a semiconductor region PACT2, a first electrode PDE2, and a second electrode PSE2 of the second sensor transistor PT2.

The third gate layer GTL3 may be located on the third gate insulating layer GI3 (e.g., disposed directly thereon in the third direction DR3). The third gate layer GTL3 may include a gate electrode PGE2 of the second sensor transistor PT2. In an embodiment, the gate electrode PGE2 of the second sensor transistor PT2 may be a portion of the reset signal line GRL.

The first source metal layer SDL1 may be located on the second interlayer insulating layer ILD2 (e.g., disposed directly thereon in the third direction DR3). The first source metal layer SDL1 may include a sensor connection electrode PCE and a first sensor node electrode NSE1. The sensor connection electrode PCE may electrically connect the reset voltage line VRL to the second electrode PSE2 of the second sensor transistor PT2. The first sensor node electrode NSE1 may electrically connect the first electrode PDE2 of the second sensor transistor PT2 to the gate electrode PGE1 of the first sensor transistor PT1.

The second source metal layer SDL2 may be located on the first via layer VIA1 (e.g., disposed directly thereon in the third direction DR3). The second source metal layer SDL2 may include the reset voltage line VRL and a second sensor node electrode NSE2. The second sensor node electrode NSE2 may electrically connect a sensor electrode PE to the first sensor node electrode NSE1.

In an embodiment, the light receiving element PD may include the sensor electrode PE, the hole transporting layer HTL, the light receiving layer RCL, the electron transporting layer ETL, and the common electrode CAT. The sensor electrode PE may be located on the second via layer VIA2 (e.g., disposed directly thereon in the third direction DR3) and may be located in the same layer as the pixel electrode AE of the light emitting element ED. The sensor electrode PE may overlap one of a plurality of sensing areas PDA defined by the pixel defining film PDL.

The hole transporting layer HTL may be located on the sensor electrode PE in the sensing area PDA (e.g., disposed directly thereon in the third direction DR3) and may be located on (e.g., disposed directly thereon) the pixel defining film PDL in an area other than the sensing area PDA. In an embodiment, the hole transporting layer HTL may be implemented as a common layer for all the light emitting pixels PX and the sensing pixels OPD, rather than being divided for each sensing pixel OPD.

The light receiving layer RCL may be located on (e.g., disposed directly thereon) the hole transporting layer HTL. The light receiving layer RCL may receive light emitted from the emission area EA and reflected by the object. The light emitted from the light emitting element ED of the emission area EA may be reflected by the object, and the reflected light may reach the light receiving layer RCL. In an embodiment, the light receiving element PD may convert the energy of light into an electrical signal (e.g., current or voltage) formed between the sensor electrode PE and the common electrode CAT, and the converted electrical signal may flow to the sensor node NS of FIG. 8 as a reverse bias current. For example, when the light receiving element PD receives light and an electric field is formed between the common electrode CAT and the sensor electrode PE of the light receiving element PD, a current may flow through the light receiving element PD in proportion to the amount of light.

The electron transporting layer ETL may be located on the light receiving layer RCL in the sensing area PDA (e.g., disposed directly thereon in the third direction DR3)and may be located on (e.g., disposed directly thereon) the hole transporting layer HTL in an area other than the sensing area PDA. In an embodiment, the electron transporting layer ETL may be implemented as a common layer for all the light emitting pixels PX and the sensing pixels OPD, rather than being divided for each sensing pixel OPD.

The common electrode CAT may be located on (e.g., disposed directly thereon) the electron transporting layer ETL. For example, the common electrode CAT may be implemented in the form of an electrode that is common to all the light emitting pixels PX and the sensing pixels OPD, rather than being divided for each of the plurality of light emitting pixels PX. In an embodiment, the common electrode CAT may be a transparent electrode and may transmit light. In an embodiment, the common electrode CAT may be electrically connected to the low potential line VSSL and may receive a low potential voltage, a common voltage, or a cathode voltage.

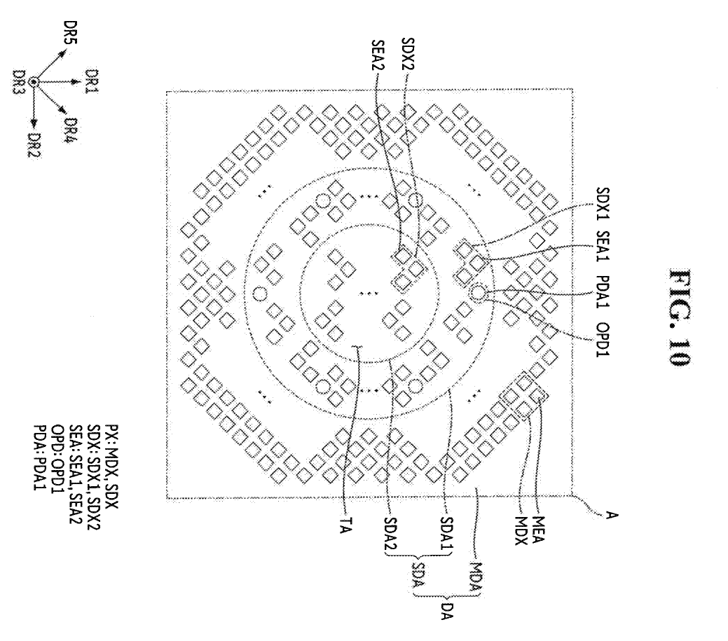

FIG. 10 is an enlarged view of area A of FIG. 2.

Referring to FIG. 10 in addition to FIGS. 6 to 9, the display area DA may include the main display area MDA and a sub-display area SDA. The sub-display area SDA may be an area where components are located under the substrate SUB of the display device 10 (e.g., in a direction opposite to the third direction DR3). In an embodiment, the sub-display area SDA may include a first sub-display area SDA1 and a second sub-display area SDA2.

In an embodiment, the light emitting pixel PX may include a main display pixel MDX located in the main display area MDA (e.g., a first display area), a first sub-display pixel SDX1 located in the first sub-display area SDA1 (e.g., a second display area), and a second sub-display pixel SDX2 located in the second sub-display area SDA2 (e.g., a third display area). Each of the main display pixels MDX may include one or more main emission areas MEA, each of the first sub-display pixels SDX1 may include one or more first sub-emission areas SEA1, and each of the second sub-display pixels SDX2 may include one or more second sub-emission areas SEA2. The light emitting element ED may be located in each of the emission areas MEA, SEA1, and SEA2 to emit light.

In an embodiment, a plurality of light emitting elements ED that emit light, and light emitting pixel circuits that are electrically connected to the light emitting element ED and apply a signal for light emission of the light emitting element ED may be located in the main display area MDA. The main display area MDA may be an area where the light emitting elements ED and the light emitting pixel circuits are arranged in a specific arrangement. In the main display area MDA, each of the light emitting elements ED may constitute the main emission area MEA, and a plurality of main emission areas MEA may constitute one main display pixel MDX. For example, in an embodiment four main emission areas MEA may constitute one main display pixel MDX. For example, one main display pixel MDX may include four main emission areas MEA, and the four main emission areas MEA may constitute one main display pixel MDX to express a white grayscale. However, the number of main emission areas MEA included in the main display pixel MDX is not necessarily limited thereto and may vary.

In some embodiments, the plurality of main display pixels MDX located in the main display area MDA may be arranged in a fourth direction DR4 and a fifth direction DR5, which are diagonal directions between the first direction DR1 and the second direction DR2. Further, the plurality of main emission areas MEA of the main display pixels MDX may be arranged in the fourth direction DR4 and the fifth direction DR5. However, the arrangement of the main display pixel MDX and the arrangement of the main emission areas MEA in the main display area MDA are not necessarily limited thereto and may be variously changed.

A plurality of light emitting elements ED that emit light, and light emitting pixel circuits that are electrically connected to the light emitting element ED and apply a signal for light emission of the light emitting element ED may be located in the sub-display area SDA. The sub-display area SDA may be an area where the light emitting elements ED and the light emitting pixel circuits are arranged in a specific arrangement.

The sub-display area SDA may be an area that overlaps a component (e.g., in the third direction DR3), for example, the optical device 700, located on the bottom surface of the substrate SUB of the display panel 100, and may have a structure in which transmittance of light is provided, unlike the main display area MDA. For example, in an embodiment the sub-display area SDA may include the first sub-display area SDA1 where both the light emitting element ED and the light emitting pixel circuits are located, and the second sub-display area SDA2 where only the light emitting element ED is located and the light emitting pixel circuit is not located.

The first sub-display area SDA1 may be located around the second sub-display area SDA2 (e.g., in a plan view). For example, in an embodiment the second sub-display area SDA2 may be located at the center, and the first sub-display area SDA1 may surround the second sub-display area SDA2 (e.g., in the plan view). However, embodiments of the present disclosure are not necessarily limited thereto, and the first sub-display area SDA1 may be located only on at least one side of the second sub-display area SDA2.

Light emitting pixel circuits of the first sub-display pixel SDX1 located in the first sub-display area SDA1 and light emitting pixel circuits of the first sub-display pixel SDX1 located in the second sub-display area SDA2 may be located in the first sub-display area SDA1. In contrast, the pixel circuits may not be located in the second sub-display area SDA2.

In an embodiment, some of the light emitting pixel circuits (e.g., a first portion) located in the first sub-display area SDA1 may be electrically connected to the light emitting element ED located in the first sub-display area SDA1, and some others of the light emitting pixel circuits (e.g., a second portion not including the first portion) may be electrically connected to the light emitting element ED located in the second sub-display area SDA2.

The second sub-display area SDA2, which is an area that overlaps (e.g., in the third direction DR3) the optical device 700 located below the display panel 100, may have high transmittance because the light emitting pixel circuits are not located therein. The second sub-display area SDA2 where the light emitting elements ED are located may emit light and have high transmittance so that the optical device 700 located on the back surface of the display panel 100 may receive light.

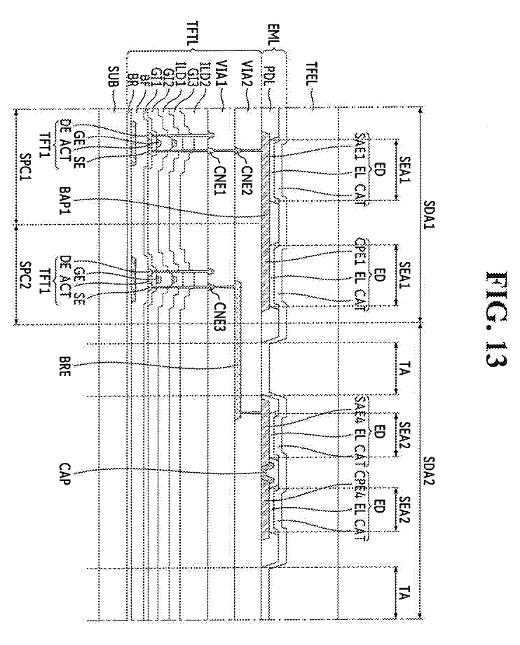

Unlike the main display area MDA, in the sub-display area SDA, one light emitting element ED and one light emitting pixel circuit may not correspond to each other. For example, one light emitting pixel circuit located in the main display area MDA may be electrically connected to one light emitting element ED. In the main display area MDA, one light emitting pixel circuit may correspond to one light emitting element ED, or a light emitting element formed in one opening of the pixel defining film PDL (see FIG. 13) to be described later. In contrast, in the sub-display area SDA, the light emitting pixel circuits located in the first sub-display area SDA1 may be electrically connected to the light emitting elements ED located in the first sub-display area SDA1 and the second sub-display area SDA2. Accordingly, in an embodiment the light emitting pixel circuit located in the first sub-display area SDA1 may correspond to a plurality of light emitting elements ED, or light emitting elements formed in a plurality of openings of the pixel defining film PDL (see FIG. 13) to be described later.

In the sub-display area SDA, each of the light emitting elements ED may constitute the first sub-emission area SEA1, and a plurality of first sub-emission areas SEA1 may constitute one first sub-display pixel SDX1. In addition, in the sub-display area SDA, each of the light emitting elements ED may constitute the second sub-emission area SEA2, and a plurality of second sub-emission areas SEA2 may constitute one second sub-display pixel SDX2. For example, in an embodiment three sub-emission areas SEA may constitute one sub-display pixel SDX. For example, one sub-display pixel SDX may include three sub-emission areas SEA, and the three sub-emission areas SEA may constitute one sub-display pixel SDX to express a white grayscale. However, the number of sub-emission areas SEA1 and SEA2 included in the sub-display pixel SDX is not necessarily limited thereto.

The sub-display pixel SDX formed by the plurality of sub-emission areas SEA of the sub-display area SDA may have an arrangement different from that of the main display pixel MDX. For example, the size and shape of the plurality of sub-emission areas SEA included in the sub-display pixel SDX may be different from the size and shape of the main emission area MEA included in the main display pixel MDX. However, embodiments of the present disclosure are not necessarily limited thereto.

In some embodiments, the plurality of sub-display pixels SDX located in the sub-display area SDA may be arranged in the fourth direction DR4 and the fifth direction DR5, which are diagonal directions between the first direction DR1 and the second direction DR2. Further, the plurality of sub-emission areas SEA of the sub-display pixels SDX may be arranged in the fourth direction DR4 and the fifth direction DR5. However, the arrangement of the sub-display pixels SDX and the arrangement of the sub-emission areas SEA1 and SEA2 in the sub-display area SDA are not necessarily limited thereto, and may be variously modified.

The second sub-display area SDA2 may further include transmission areas TA that transmit light. The transmission area TA is an area through which light incident on the display panel 100 passes (e.g., is transmitted therethrough). The transmission area TA is an area having transmittance (e.g., a transmittance for visible light) higher than the transmittance (e.g., a transmittance for visible light) of the area where the sub-display pixel SDX is located. The transmission area TA located in the sub-display area SDA may be an area where the second sub-display pixel SDX2 is not located. The transmission area TA may be an area where the pixel defining film PDL (see FIG. 13) to be described later is not located.

The transmission area TA may be located adjacent to the second sub-emission areas SEA2 (e.g., in a plan view). The transmission area TA may not overlap the second sub-emission areas SEA2. The transmission area TA may surround the second sub-emission areas SEA2 (e.g., in a plan view).

In addition, since the sub-display area SDA includes the transmission area TA, the density of the sub-display pixel SDX in the sub-display area SDA may be lower than the density of the main display pixel MDX in the main display area MDA. Accordingly, the luminance and resolution of the sub-display area SDA may be different from those of the main display area MDA.

Due to the transmission areas TA, the number of sub-emission areas SEA per unit area in the sub-display area SDA may be different from the number of main emission areas MEA per unit area in the main display area MDA. For example, in an embodiment the number of sub-emission areas SEA per unit area in the sub-display area SDA may be less than the number of main emission areas MEA per unit area in the main display area MDA.

In addition, a ratio of the area of the sub-emission areas SEA to the area of the sub-display area SDA may be different from a ratio of the area of the main emission areas MEA to the area of the main display area MDA, due to the transmission areas TA. For example, in an embodiment a ratio of the area of the sub-emission areas SEA to the area of the sub-display area SDA may be less than a ratio of the area of the main emission areas MEA to the area of the main display area MDA.

In addition, in an embodiment the light receiving element PD and the sensing pixel circuit that is electrically connected to the light receiving element PD and receives a sensing signal of the light receiving element PD may be further located in the sub-display area SDA. The sub-display area SDA may be an area where the light receiving elements PD and the sensing pixel circuits are arranged in specific arrangement. In the sub-display area SDA, each of the light receiving elements PD may constitute the sensing area PDA, and at least one sensing area PDA may constitute one sensing pixel OPD. For example, in the first sub-display area SDA1, each of the light receiving elements PD may constitute a first sensing area PDA1, and the first sensing area PDA1 may constitute a first sensing pixel OPD1.

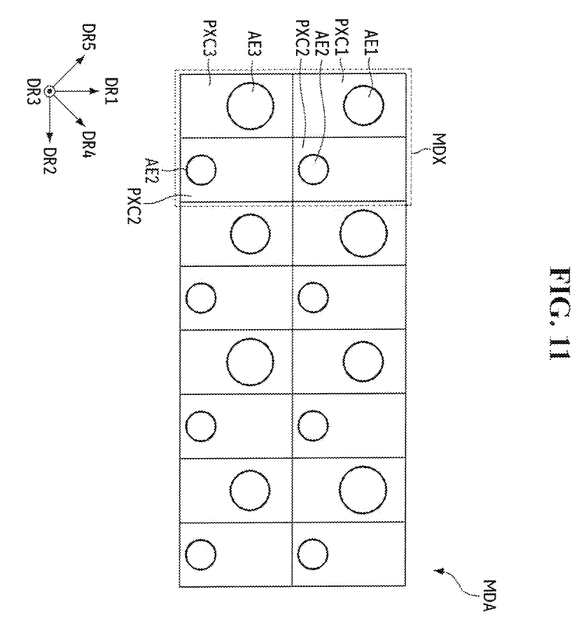

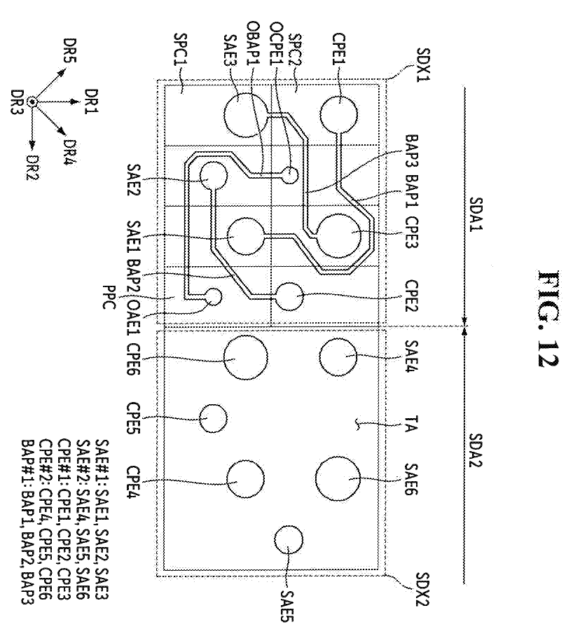

FIG. 11 is a plan view of the arrangement of pixel electrodes in the main display area of the display device according to an embodiment. FIG. 12 is a plan view showing the arrangement of pixel electrodes and the arrangement of sensor electrodes in a sub-display area of a display device according to an embodiment.

Referring to FIGS. 11 and 12 in addition to FIGS. 6 to 10, the display device 10 according to an embodiment may include a plurality of pixel electrodes AE1, AE2, and AE3 located in the main display area MDA. In an embodiment, the pixel electrodes AE1, AE2, and AE3 may be anode electrodes of the light emitting elements ED that emit lights of different colors from each other. For example, the first pixel electrode AE1, which is the anode electrode of the light emitting element that emits light of the first color, may be located in a first emission area. The second pixel electrode AE2, which is the anode electrode of the light emitting element that emits light of the second color, may be located in a second emission area, and the third pixel electrode AE3, which is the anode electrode of the light emitting element that emits light of the third color, may be located in a third emission area. In an embodiment, the first emission area may emit first light of a red color, the second emission area may emit second light of a green color, and the third emission area may emit third light of a blue color. However, embodiments of the present disclosure are not necessarily limited thereto and the respective colors emitted by the first to third emission areas may vary. The plurality of emission areas may be respectively defined by the openings formed in the pixel defining film PDL of the light emitting element layer EML to be described later.

In an embodiment, the plurality of pixel electrodes AE1, AE2, and AE3 may be located in a PenTile^{TM} type, such as a diamond PenTile^{TM} type. For example, in an embodiment the first pixel electrode AE1 and the third pixel electrode AE3 may be located to be spaced apart from each other in the first direction DR1 and the second direction DR2, and they may be located alternately. The second pixel electrode AE2 may be spaced apart from another adjacent second pixel electrode AE2 in the first direction DR1 and the second direction DR2, and may be spaced apart from the adjacent first pixel electrode AE1 and the adjacent third pixel electrode AE3 in a diagonal direction (e.g. the fourth or fifth directions DR4, DR5).

Each of the plurality of pixel circuits PXC1, PXC2, and PXC3 located in the main display area MDA may correspond to one of the pixel electrodes AE1, AE2, and AE3. For example, the first pixel circuit PXC1 may correspond to one first pixel electrode AE1 and be electrically connected thereto. The second pixel circuit PXC2 may correspond to one second pixel electrode AE2 and be electrically connected thereto, and the third pixel circuit PXC3 may correspond to one third pixel electrode AE3 and be electrically connected thereto. The main display pixel MDX including the four pixel electrodes AE1, AE2, and AE3 may include the four pixel circuits PXC1, PXC2, and PXC3. For example, in an embodiment the main display pixel MDX may include two second pixels each having a second pixel electrode AE2 and a second pixel circuit PXC2, one first pixel having the first pixel electrode AE1 and the first pixel circuit PXC1 and one third pixel having the third pixel electrode AE3 and the third pixel circuit PXC3.

In an embodiment, the display device 10 may include a plurality of sub-pixel electrodes SAE1 to SAE6, a plurality of copy pixel electrodes CPE1 to CPE6, and bridge portions BAP1, BAP2, and BAP3 that are located in the sub-display area SDA. One of the sub-pixel electrodes SAE1 to SAE6 and one of the copy pixel electrodes CPE1 to CPE6 may each be the anode electrode of the light emitting element ED. For example, similarly to the main display area MDA, the light emitting elements ED may also be located in the sub-display areas SDA1 and SDA2 to emit light.

The configuration of the sub-display pixels SDX1 and SDX2 of the sub-display area SDA may be different from that of the main display pixel MDX of the main display area MDA. In an embodiment, in the first sub-display pixel SDX1, one of the sub-pixel electrodes SAE1 to SAE6 and one of the copy pixel electrodes CPE1 to CPE6 may be electrically connected to each other through the bridge portion BAP1, BAP2, BAP3. The sub-pixel electrodes SAE1 to SAE6 and the copy pixel electrodes CPE1 to CPE6 connected through the bridge portions BAP1, BAP2, and BAP3 may each be the anode electrode of the light emitting element ED that emits light of the same color.

For example, in an embodiment the first sub-pixel electrode SAE1 and a first copy pixel electrode CPE1 located in the first sub-display area SDA1 may be electrically connected to each other through a first bridge portion BAP1, and they may constitute a light emitting element that emits light of the first color. The emission areas where the first sub-pixel electrode SAE1 and the first copy pixel electrode CPE1 are located may emit light of the same color.

Similarly, in an embodiment the second sub-pixel electrode SAE2 and a second copy pixel electrode CPE2 located in the first sub-display area SDA1 may be electrically connected to each other through a second bridge portion BAP2, and the third sub-pixel electrode SAE3 and a third copy pixel electrode CPE3 located in the first sub-display area SDA1 may be electrically connected to each other through a third bridge portion BAP3. The second sub-pixel electrode SAE2 and the second copy pixel electrode CPE2 may constitute a light emitting element that emits light of the second color, and the third sub-pixel electrode SAE3 and the third copy pixel electrode CPE3 may constitute a light emitting element that emits light of the third color. The emission areas where the second sub-pixel electrode SAE2 and the second copy pixel electrode CPE2 are located may emit light of the same color, and the emission areas where the third sub-pixel electrode SAE3 and the third copy pixel electrode CPE3 are located may emit light of the same color.

In accordance with an embodiment, the sub-pixel electrodes SAE4, SAE5, and SAE6 and copy pixel electrodes CPE4, CPE5, and CPE6 located in the second sub-display area SDA2 may be electrically connected to each other through a connection pattern CAP (see FIG. 13). In an embodiment, the fourth to sixth sub-pixel electrodes SAE4, SAE5, and SAE6 and the fourth to sixth copy pixel electrodes CPE4, CPE5, and CPE6 may also be arranged in the second sub-display area SDA2 in the same arrangement as that in the first sub-display area SDA1. However, a pair of the sub-pixel electrodes SAE4, SAE5, and SAE6 and the copy pixel electrodes CPE4, CPE5, and CPE6 may be connected through connection patterns located around them.

In an embodiment, the fourth sub-pixel electrode SAE4 and the fourth copy pixel electrode CPE4 may constitute a light emitting element that emits light of the first color, the fifth sub-pixel electrode SAE5 and the fifth copy pixel electrode CPE5 may constitute a light emitting element that emits light of the second color, and the sixth sub-pixel electrode SAE6 and the sixth copy pixel electrode CPE6 may constitute a light emitting element that emits light of the third color.

In an embodiment the plurality of sub-pixel electrodes SAE1 to SAE6 and the plurality of copy pixel electrodes CPE1 to CPE6 may be arranged in a PenTile^{TM} type, e.g., a diamond PenTile^{TM} type, similarly to the pixel electrode AE of the main display area MDA. For example, the first sub-pixel electrode SAE1 and the third sub-pixel electrode SAE3 may be spaced apart from each other in the second direction DR2, and the third copy pixel electrode CPE3 and the first copy pixel electrode CPE1 may be located to be spaced apart therefrom in the first direction DR1. The fourth sub-pixel electrode SAE4 and the sixth sub-pixel electrode SAE6 may be spaced apart from each other in the second direction DR2, and the sixth copy pixel electrode CPE6 and the fourth copy pixel electrodes CPE4 may be located to be spaced apart therefrom in the first direction DR1. The second sub-pixel electrode SAE2 and the second copy pixel electrode CPE2 may be spaced apart from each other in the diagonal direction (e.g., the fourth direction DR4) with the first sub-pixel electrode SAE1 interposed between the second sub-pixel electrode SAE2 and the second copy pixel electrode CPE2. The fifth sub-pixel electrode SAE5 and the fifth copy pixel electrode CPE5 may be spaced apart from each other in the diagonal direction (e.g., the fourth direction DR4) with the fourth copy pixel electrode CPE4 interposed between the fifth sub-pixel electrode SAE5 and the fifth copy pixel electrode CPE5. In an embodiment, the plurality of bridge portions BAP1, BAP2, and BAP3 may connect a pair of the sub-pixel electrodes SAE1 to SAE3 and the copy pixel electrodes CPE1 to CPE3 to each other, and may bypass other sub-pixel electrodes SAE1 to SAE3, other copy pixel electrodes CPE1 to CPE3, and other bridge portions BAP1, BAP2, and BAP3 without crossing them.

In an embodiment, the first sub-display pixel SDX1 located in the first sub-display area SDA1 may include six pixel electrodes including the first to third sub-pixel electrodes SAE1, SAE2, and SAE3 and the first to third copy pixel electrodes CPE1, CPE2, and CPE3, or six emission areas. In an embodiment, the second sub-display pixel SDX2 located in the second sub-display area SDA2 may include six pixel electrodes including the fourth to sixth sub-pixel electrodes SAE4, SAE5, and SAE6 and the fourth to sixth copy pixel electrodes CPE4, CPE5, and CPE6, or six emission areas. Unlike the main display pixel MDX of the main display area MDA, the sub-display pixels SDX1 and SDX2 located in the sub-display area SDA may have a larger number of emission areas that emit light of the same color. However, the number or density of emission areas per unit area may be larger in the main display pixel MDX than in the sub-display pixels SDX1 and SDX2. Further, the number of the light emitting elements that emit light of the first color and the number of light emitting elements that emit light of the third color may be larger in the sub-display pixel SDX than in the main display pixel MDX, but the number of light emitting elements that emit light of the second color may be the same in the sub-display pixels SDX1 and SDX2 and the main display pixel MDX. Accordingly, the resolution of the main display area MDA may be higher than that of the sub-display area SDA. The sub-display area SDA may have the resolution lower than that of the main display area MDA in consideration of the transmittance of light incident on the optical device 700 located under the sub-display area SDA.

In an embodiment, a first sub-pixel circuit SPC1 electrically connected to the first sub-display pixel SDX1 and a second sub-pixel circuit SPC2 electrically connected to the second sub-display pixel SDX2 may be located in the first sub-display area SDA1 of the sub-display area SDA. In an embodiment the first sub-pixel circuit SPC1 and the second sub-pixel circuit SPC2 may be spaced apart from each other in the first direction DR1. In contrast, the pixel circuit may not be located in the second sub-display area SDA2 and the plurality of sub-pixel electrodes SAE4 to SAE6, the plurality of copy pixel electrodes CPE4 to CPE6, the connection pattern CAP (see FIG. 13), and a bridge electrode BRE (see FIG. 13) that electrically connects them to the second sub-pixel circuit SPC2 may be located therein.

The plurality of sub-pixel electrodes SAE1 to SAE6 and the plurality of copy pixel electrodes CPE1 to CPE6 are located in the first and second sub-display areas SDA1 and SDA2, and they may be distinguished depending on the arrangement position and the connection structure. For example, in an embodiment the first to third sub-pixel electrodes SAE1, SAE2, and SAE3 located in the first sub-display area SDA1 may be located in the same layer as each other, and may be connected to the first to third copy pixel electrodes CPE1, CPE2, and CPE3 through the first to third bridge portions BAP1, BAP2, and BAP3 that are integrated (e.g., respectively formed integrally with each other). The sub-pixel electrodes SAE1 to SAE6, the copy pixel electrodes CPE1 to CPE6, and the bridge portions BAP1, BAP2, and BAP3 located in the first sub-display area SDA1 may constitute substantially the same electrode (e.g., one electrode connected physically) and may have substantially the same material and cross-sectional structure. The electrodes and bridge portion(s) integrally formed with each other as one electrode connected physically may be collectively referred to as an “integrated electrode”. The sub-pixel electrodes SAE1 to SAE3 and the copy pixel electrodes CPE1 to CPE3 located in the first sub-display area SDA1 may be referred to as a first type sub-pixel electrode SAE#1 (or 'first sub-pixel electrode') and a first type copy pixel electrode CPE#1 (or 'first copy pixel electrode'), respectively.

In contrast, the fourth to sixth sub-pixel electrodes SAE4, SAE5, and SAE6 located in the second sub-display area SDA2 may be connected to the fourth to sixth copy pixel electrodes CPE4, CPE5, and CPE6 through patterns that are located in the same layer but are physically distinguished from each other. A pattern (e.g., electrode) that is physically distinguished from another electrode and not formed integrally therewith may be referred to as a “separate electrode”. A plurality of connection patterns CAP (see FIG. 13) surrounding (e.g., in a plan view) the fourth to sixth sub-pixel electrodes SAE4, SAE5, and SAE6 and the fourth to sixth copy pixel electrodes CPE4, CPE5, and CPE6 may be located in the second sub-display area SDA2. The fourth to sixth sub-pixel electrodes SAE4, SAE5, and SAE6 and the fourth to sixth copy pixel electrodes CPE4, CPE5, and CPE6 may be connected to each other by the plurality of connection patterns CAP (see FIG. 13). The sub-pixel electrodes SAE4 to SAE6 and the copy pixel electrodes CPE4 to CPE6 located in the second sub-display area SDA2 may be referred to as a second type sub-pixel electrode SAE#2 (or 'second sub-pixel electrode') and a second type copy pixel electrode CPE#2 (or 'second copy pixel electrode'), respectively.

In an embodiment, the first sub-pixel circuit SPC1 may be electrically connected to the first type sub-pixel electrode SAE#1, or the sub-pixel electrodes SAE1 to SAE3 located in the first sub-display pixel SDX1. Each of the plurality of first sub-pixel circuits SPC1 may be electrically connected to the first sub-pixel electrode SAE1, the second sub-pixel electrode SAE2, and the third sub-pixel electrode SAE3. Each of the first type copy pixel electrodes CPE#1 located in the first sub-display pixel SDX1 may be electrically connected to the first type sub-pixel electrode SAE#1 through the bridge portions BAP1, BAP2, and BAP3, and a plurality of light emitting elements including a pair of the sub-pixel electrode SAE1 to SAE3 and the copy pixel electrode CPE1 to CPE3 may emit light simultaneously. Each of the sub-pixel electrodes SAE1 to SAE3 located in the first sub-display pixel SDX1 may be located to overlap the first sub-pixel circuit SPC1.

In an embodiment, the second sub-pixel circuit SPC2 may be electrically connected to the second type sub-pixel electrode SAE#2, or the sub-pixel electrodes SAE4 to SAE6 located in the second sub-display pixel SDX2. Each of the plurality of second sub-pixel circuits SPC2 may be electrically connected to the fourth sub-pixel electrode SAE4, the fifth sub-pixel electrode SAE5, and the sixth sub-pixel electrode SAE6. Each of the second type copy pixel electrodes CPE#2 located in the second sub-display pixel SDX2 may be electrically connected to the second type sub-pixel electrode SAE#2 through the connection pattern CAP (see FIG. 13), and a plurality of light emitting elements including a pair of the sub-pixel electrodes SAE4 to SAE6 and the copy pixel electrodes CPE4 to CPE6 may emit light simultaneously. The connection patterns CAP (see FIG. 13) that connect the second sub-pixel circuit SPC2 and the sub-pixel electrode SAE#2 of the second sub-display pixel SDX2 may be located in the sub-display area SDA and may extend from the first sub-display area SDA1 to the second sub-display area SDA2. In an embodiment, at least some of the copy pixel electrodes CPE#1 located in the first sub-display pixel SDX1 may be located to overlap the second sub-pixel circuit SPC2. Some others of the copy pixel electrodes CPE#1 located in the first sub-display pixel SDX1 may be located in the area where the sub-pixel circuits SPC1 and SPC2 are not located.

In accordance with an embodiment, the sub-pixel electrodes SAE#1, the copy pixel electrodes CPE#1, and the bridge portions BAP#1 that are located in the first sub-display area SDA1 may be located in the same layer as each other to form an integrated pattern (e.g., an integrated electrode). For example, in an embodiment the first to third bridge portions BAP1, BAP2, and BAP3 located in the first sub-display area SDA1 may be bridge portions integrated with the first to third sub-pixel electrodes SAE1, SAE2, and SAE3 and the first to third copy pixel electrodes CPE1, CPE2, and CPE3, respectively. In contrast, the sub-pixel electrodes SAE#2 and the copy pixel electrodes CPE#2 located in the second sub-display area SDA2 may be located in the same layer and have the same electrode structure, but the connection pattern CAP (see FIG. 13) located therearound may contain a different material and have a different structure (e.g., a separate electrode). In an embodiment, the connection pattern CAP (see FIG. 13) located in the second sub-display area SDA2 may be located in the same layer as the sub-pixel electrodes SAE#2 and the copy pixel electrodes CPE#2 located in the second sub-display area SDA2, and may be electrically connected to them by direct contact therewith.

The sub-pixel electrodes SAE#1 located in the first sub-display area SDA1 may be located to overlap the first sub-pixel circuit SPC1, and may be integrated with the copy pixel electrode CPE#1 through the bridge portions BAP#1 in the same layer. The sub-pixel electrodes SAE#2 located in the second sub-display area SDA2 may be electrically connected to the second sub-pixel circuit SPC2 but may be located so as not to overlap the second sub-pixel circuit SPC2 (e.g., in the third direction DR3). In an embodiment, the sub-pixel electrodes SAE#2 located in the second sub-display area SDA2 may be electrically connected to the second sub-pixel circuit SPC2 through the bridge electrodes BRE (e.g., a second connection electrode) located under the sub-pixel electrodes SAE#2 and extending from the first sub-display area SDA1 to the second sub-display area SDA2.

In the sub-display area SDA, the sub-pixel circuits SPC1 and SPC2 may be located only in the first sub-display area SDA1 to provide for the increased transmittance in the second sub-display area SDA2. Since the number of sub-pixel circuits SPC1 and SPC2 located per unit area is smaller in the sub-display area SDA than in the main display area MDA, the sub-pixel electrodes SAE1 to SAE6 and the copy pixel electrodes CPE1 to CPE6 may form a pair to form a plurality of emission areas in the case of the sub-display pixels SDX1 and SDX2 located in the sub-display area SDA.

Hereinafter, the cross-sectional structures of the sub-pixel electrodes SAE#1, the copy pixel electrodes CPE#1, and the bridge portion BAP#1 that are located in the first sub-display area SDA1, and the sub-pixel electrodes SAE#2, the copy pixel electrodes CPE#2, and the connection pattern CAP that are located in the second sub-display area SDA2 will be described with reference to FIG. 13. In FIG. 13, the first sub-pixel electrode SAE1, the first copy pixel electrode CPE1, the first bridge portion BAP1, the fourth sub-pixel electrode SAE4, the fourth copy pixel electrode CPE4, and the connection pattern CAP are described as examples, but the same technical spirit may also be applied to the other second to sixth sub-pixel electrodes SAE2 to SAE6, the other second to sixth copy pixel electrodes CPE2 to CPE6, the second and third bridge portions BAP2 and BAP3, and the other connection pattern CAP.

FIG. 13 is a cross-sectional view showing light emitting elements in a sub-display area of a display device according to an embodiment.

Referring to FIG. 13, the first sub-pixel electrode SAE1 and the first copy pixel electrode CPE1 located in the first sub-display area SDA1 may be connected to each other through the first bridge portion BAP1. For example, in an embodiment the first sub-pixel electrode SAE1, the first copy pixel electrode CPE1, and the first bridge portion BAP1 may be electrodes that are integrated with each other (e.g., an integrated electrode). In an embodiment, the first sub-pixel electrode SAE1, the first copy pixel electrode CPE1, and the first bridge portion BAP1 may constitute substantially the same electrode (e.g., one electrode connected physically) and may have substantially the same material and cross-sectional structure as each other.

The first sub-pixel circuit SPC1 connected to the first sub-pixel electrode SAE1 may be located in the first sub-display area SDA1. The first sub-pixel electrode SAE1 may overlap the first sub-pixel circuit SPC1 (e.g., in the third direction DR3). The first sub-pixel electrode SAE1 may be connected to the first thin film transistor TFT1 of the first sub-pixel circuit SPC1 through the first connection electrode CNE1 and the second connection electrode CNE2.

The first thin film transistor TFT1 of the first sub-pixel circuit SPC1 may be any one of the first to eighth transistors ST1 to ST8 described with reference to FIGS. 6 and 7. For example, in an embodiment the first thin film transistor TFT1 may include a gate electrode GE, a semiconductor region ACT, a first electrode DE, and a second electrode SE, similarly to the first transistor ST1, the second transistor ST2, and the third transistor ST3 of FIG. 7.

In contrast, the fourth sub-pixel electrode SAE4 and the fourth copy pixel electrode CPE4 located in the second sub-display area SDA2 may be connected to each other through a connection pattern CAP. For example, in an embodiment the fourth sub-pixel electrode SAE4, the fourth copy pixel electrode CPE4, and the connection pattern CAP may be electrodes that are physically distinguished from each other. For example, the fourth sub-pixel electrode SAE4, the fourth copy pixel electrode CPE4, and the connection pattern CAP may not be integrally formed with each other (e.g., a separate electrode). The fourth sub-pixel electrode SAE4, the fourth copy pixel electrode CPE4, and the connection pattern CAP may be configured as separate electrodes that are physically distinguished and may have substantially different materials and cross-sectional structures from each other. For example, the connection pattern CAP may be composed of a different material and have a different cross-sectional structure from each of the fourth sub-pixel electrode SAE4 and the fourth copy pixel electrode CPE4. In some embodiments, the fourth sub-pixel electrode SAE4 and the fourth copy pixel electrode CPE4 may be spaced apart from each other (e.g., in a plan view) but may be formed from a same material having a same cross-sectional structure as each other.

The second sub-pixel circuit SPC2 connected to the fourth sub-pixel electrode SAE4 may be located in the first sub-display area SDA1. In an embodiment, the fourth sub-pixel electrode SAE4 may be connected to the first thin film transistor TFT1 of the second sub-pixel circuit SPC2 through the bridge electrode BRE and the third connection electrode CNE3. The bridge electrode BRE may be referred to as a “connection electrode”. The bridge electrode BRE extends from the first sub-display area SDA1 to the second sub-display area SDA2. The fourth sub-pixel electrode SAE4 may not overlap the second sub-pixel circuit SPC2 (e.g., in a third direction DR3).

In some embodiments, the bridge electrode BRE overlapping the transmission area TA may be a transparent electrode. For example, in an embodiment the bridge electrode BRE may include a transparent conductive material (TCO) such as ITO or IZO. Accordingly, the transmittance of the transmission area TA may be increased.

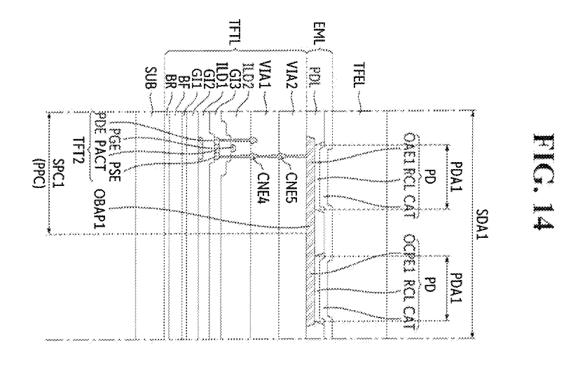

Hereinafter, a first sensor electrode OAE1, a first copy sensor electrode OCPE1, and a first sensor bridge portion OBAP1 will be described with reference to FIGS. 12 and 14.

FIG. 14 is a cross-sectional view showing light receiving elements in a sub-display area of a display device according to an embodiment.

Referring to FIG. 14 in addition to FIG. 12, in an embodiment the display device 10 may further include the first sensor electrode OAE1 (e.g., a first sub-sensor electrode), the first copy sensor electrode OCPE1, and the first sensor bridge portion OBAP1 that are located in the first sub-display area SDA1. The first sensor electrode OAE1 and the first copy sensor electrode OCPE1 may each be the anode electrode of the light receiving element PD. The light receiving element PD may be further located in the sub-display area SDA to collect light.

The first sensor electrode OAE1 and the first copy sensor electrode OCPE1 may be located in an area of the first sub-display area SDA1 where the first type sub-pixel electrode SAE#1 and the first type copy pixel electrode CPE#1 are not located.

For example, in an embodiment the first sensor electrode OAE1 may be spaced apart from the second sub-pixel electrode SAE2 in the second direction DR2, and may be spaced apart from the second copy pixel electrode CPE2 in the first direction DR1. The first sensor electrode OAE1 may be spaced apart from the first sub-pixel electrode SAE1 in the fifth direction DR5. In addition, the first copy sensor electrode OCPE1 may be spaced apart from the second sub-pixel electrode SAE2 in the first direction DR1, and may be spaced apart from the second copy pixel electrode CPE2 in the second direction DR2. The first copy sensor electrode OCPE1 may be spaced apart from the third sub-pixel electrode SAE3 and the third copy pixel electrode CPE3 in the fourth direction DR4, and may be spaced apart from the first sub-pixel electrode SAE1 and the first copy pixel electrode CPE1 in the fifth direction DR5.

The first sensor electrode OAE1 and the first copy sensor electrode OCPE1 may be electrically connected to each other through the first sensor bridge portion OBAP1. In an embodiment, the first sensor bridge portion OBAP1 may connect the first sensor electrode OAE1 and the first copy sensor electrode OCPE1 to each other and may bypass other sub-pixel electrodes SAE1 to SAE3, other copy pixel electrodes CPE1 to CPE3, and other bridge portions BAP1, BAP2, and BAP3 without crossing them.

As illustrated in FIG. 14, the first sensor electrode OAE1 located in the first sub-display area SDA1 may be connected to the first copy sensor electrode OCPE1 through the first sensor bridge portion OBAP1 that is located in the same layer as the first sensor electrode OAE1 and may be integrated with the first sensor electrode OAE1 (e.g., an integrated electrode). The first sensor electrode OAE1, the first copy sensor electrode OCPE1, and the first sensor bridge portion OBAP1 that are located in the first sub-display area SDA1 may constitute substantially the same electrode (e.g., one electrode connected physically) and may have substantially the same material and cross-sectional structure as each other.

In an embodiment, the light receiving element PD is located in the first sub-display area SDA1 and the light receiving element PD is not located in the second sub-display area SDA2, so that the first sub-pixel circuit SPC1 may include a sensing pixel circuit PPC electrically connected to the first sensor electrode OAE1 and the first copy sensor electrode OCPE1, whereas the second sub-pixel circuit SPC2 may not include the sensing pixel circuit PPC.

As illustrated in FIG. 14, the sensing pixel circuit PPC may be electrically connected to the first sensor electrode OAE1. The first copy sensor electrode OCPE1 located in the first sub-display pixel SDX1 may be electrically connected to the first sensor electrode OAE1 through the first sensor bridge portion OBAP1.

In the sub-display area SDA, to provide for the increased transmittance in the second sub-display area SDA2, the sensing pixel circuit PPC, and the first sensor electrode OAE1 and the first copy sensor electrode OCPE1 of the light receiving element PD may be located only in the first sub-display area SDA1. Since the sensing pixel circuit PPC, and the first sensor electrode OAE1 and the first copy sensor electrode OCPE1 of the light receiving element PD are not located in the second sub-display area SDA2, the area of the transmission area TA is increased and the second sub-display area SDA2 has an increased transmittance.

The sensing pixel circuit PPC of the first sub-pixel circuit SPC1, which is connected to the first sensor electrode OAE1, may be located solely in the first sub-display area SDA1. The first sensor electrode OAE1 may overlap the sensing pixel circuit PPC (e.g., in the third direction DR3). The first sensor electrode OAE1 may be connected to the second thin film transistor TFT2 of the sensing pixel circuit PPC through a fourth connection electrode CNE4 and a fifth connection electrode CNE5.

The second thin film transistor TFT2 of the sensing pixel circuit PPC may be any one of the first to third sensor transistors PT1 to PT3 described with reference to FIGS. 8 and 9. For example, the second thin film transistor TFT2 of the sensing pixel circuit PPC may include the gate electrode PGE, the semiconductor region PACT, the first electrode PDE, and the second electrode PSE, similarly to the first sensor transistor PT1 and the second sensor transistor PT2 of FIG. 9.

In the display device 10 according to an embodiment, light may be sensed by the light receiving element PD embedded in the sub-display area SDA. Therefore, the optical sensor is embedded in the display panel 100 itself, so that an optical sensor such as a proximity sensor or a gesture sensor may not be provided as a separate optical device 700 under the sub-display area SDA. Accordingly, the manufacturing cost may be reduced, and the module of the display device 10 may have increased compactness.

Hereinafter, embodiments of the display device will be described. In the following embodiments, description of the same components as those of the above-described embodiment, which are denoted by like reference numerals, will be omitted or simplified, and differences will be mainly described.

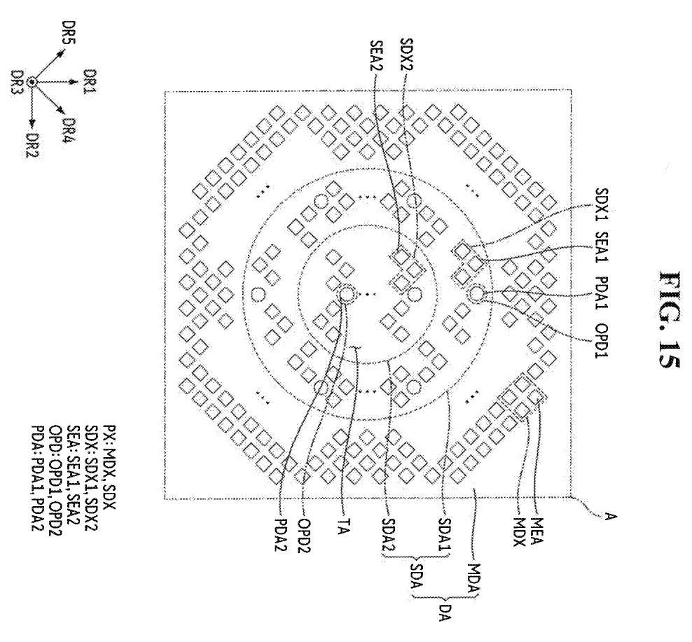

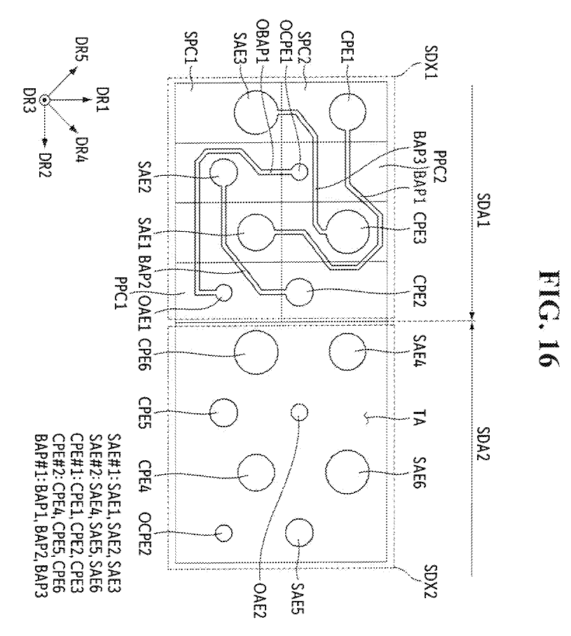

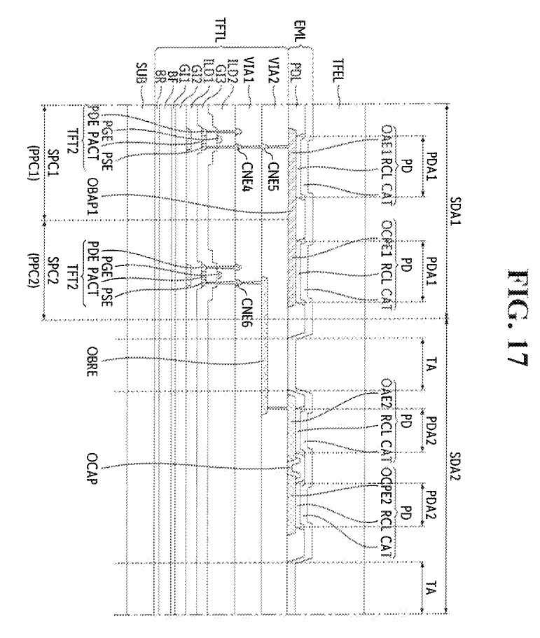

FIG. 15 is a plan view illustrating a display area of a display device according to an embodiment. FIG. 16 is a plan view showing the arrangement of pixel electrodes and the arrangement of sensor electrodes in the sub-display area of the display device according to an embodiment of FIG. 15. FIG. 17 is a cross-sectional view showing light receiving elements in the sub-display area of the display device according to an embodiment of FIG. 15.

Referring to FIGS. 15 to 17, the display device 10 according to an embodiment is different from the display device 10 according to an embodiment described with reference to FIG. 10 or the like in that the light receiving element PD is also located in the second sub-display area SDA2.

More specifically, in the display device 10 according to an embodiment, the light receiving element PD may also be located in the second sub-display area SDA2 as well as the first sub-display area SDA1. For example, in an embodiment in the first sub-display area SDA1, each of the light receiving elements PD may constitute the first sensing area PDA1, and the first sensing area PDA1 may constitute the first sensing pixel OPD1, and in the second sub-display area SDA2, each of the light receiving elements PD may constitute the second sensing area PDA2, and the second sensing area PDA2 may constitute the second sensing pixel OPD2.

The display device 10 according to an embodiment may further include a second sensor electrode OAE2 (e.g., a second sub-sensor electrode), a second copy sensor electrode OCPE2, and a sensor connection pattern OCAP that are located in the second sub-display area SDA2. The second sensor electrode OAE2 and the second copy sensor electrode OCPE2 may each be the anode electrode of the light receiving element PD. The light receiving element PD may be further located in the second sub-display area SDA2 to collect light.

The second sensor electrode OAE2 and the second copy sensor electrode OCPE2 may be located in an area of the second sub-display area SDA2 where the second type sub-pixel electrode SAE#2 and the second type copy pixel electrode CPE#2 are not located.

For example, in an embodiment the second sensor electrode OAE2 may be spaced apart from the fifth sub-pixel electrode SAE5 in the second direction DR2, and may be spaced apart from the fifth copy pixel electrode CPE5 in the first direction DR1. The second sensor electrode OAE2 may be spaced apart from the sixth sub-pixel electrode SAE6 and the sixth copy pixel electrode CPE6 in the fourth direction DR4, and may be spaced apart from the fourth sub-pixel electrode SAE4 and the fourth copy pixel electrode CPE4 in the fifth direction DR5. In addition, the second copy sensor electrode OCPE2 may be spaced apart from the fifth sub-pixel electrode SAE5 in the first direction DR1, and may be spaced apart from the fifth copy pixel electrode CPE5 in the second direction DR2. The second copy sensor electrode OCPE2 may be spaced apart from the fourth copy pixel electrode CPE4 in the fifth direction DR5.

In an embodiment, the second sensor electrode OAE2 and the second copy sensor electrode OCPE2 may be electrically connected to each other through the sensor connection pattern OCAP. The second sensor electrode OAE2 and the second copy sensor electrode OCPE2 may also be arranged in the second sub-display area SDA2 in the same arrangement as that in the first sub-display area SDA1. However, a pair of the second sensor electrode OAE2 and the second copy sensor electrode OCPE2 may be connected through the sensor connection pattern OCAP located around them.

For example, as illustrated in FIG. 17, in the first sub-display area SDA1, the first sensor electrode OAE1 and the first copy sensor electrode OCPE1 may be connected to each other through the first sensor bridge portion OBAP1 that is located in the same layer as the first sensor electrode OAE1 and the first copy sensor electrode OCPE1 and integrated with the first sensor electrode OAE1 and the first copy sensor electrode OCPE1 (e.g., an integrated electrode). In contrast, the second sensor electrode OAE2 located in the second sub-display area SDA2 may be connected to the second copy sensor electrode OCPE2 through the sensor connection pattern OCAP that is located in the same layer as the second sensor electrode OAE2 but is physically distinguished from the second sensor electrode OAE2 (e.g., a separate electrode). The sensor connection pattern OCAP surrounding the second sensor electrode OAE2 and the second copy sensor electrode OCPE2 may be located in the second sub-display area SDA2.

The second sensor electrode OAE2, the second copy sensor electrode OCPE2, and the sensor connection pattern OCAP may be electrodes that are physically distinguished from each other. For example, the second sensor electrode OAE2, the second copy sensor electrode OCPE2, and the sensor connection pattern OCAP may be configured as separate electrodes that are physically distinguished and may have substantially different materials and cross-sectional structures from each other. For example, in an embodiment the sensor connection pattern OCAP may be composed of a different material and have a different cross-sectional structure from each of the second sensor electrode OAE2 and the second copy sensor electrode OCPE2. In some embodiments, the second sensor electrode OAE2 and the second copy sensor electrode OCPE2 may be spaced apart from each other (e.g., in a plan view) but may be formed from a same material having a same cross-sectional structure as each other.

In an embodiment, the light receiving element PD is located in both the first sub-display area SDA1 and the second sub-display area SDA2, so that the first sub-pixel circuit SPC1 may include a first sensing pixel circuit PPC1 electrically connected to the first sensor electrode OAE1 and the first copy sensor electrode OCPE1, and the second sub-pixel circuit SPC2 may include a second sensing pixel circuit PPC2 electrically connected to the second sensor electrode OAE2 and the second copy sensor electrode OCPE2.

As illustrated in FIG. 17, the second sensing pixel circuit PPC2 located in the first sub-display area SDA1 may be electrically connected to the second sensor electrode OAE2 located in the second sub-display area SDA2. The second copy sensor electrode OCPE2 located in the second sub-display pixel SDX2 may be electrically connected to the second sensor electrode OAE2 through the sensor connection pattern OCAP.

To provide the increased transmittance in the second sub-display area SDA2, the first sensing pixel circuit PPC1 and the second sensing pixel circuit PPC2 may be located only in the first sub-display area SDA1. However, the light receiving element PD may be located in both the first sub-display area SDA1 and the second sub-display area SDA2.

In an embodiment, the first sensor electrode OAE1 and the first copy sensor electrode OCPE1 located in the first sub-display area SDA1 may include an opaque electrode, whereas the second sensor electrode OAE2 and the second copy sensor electrode OCPE2 located in the second sub-display area SDA2 may include a transparent electrode. For example, in an embodiment the second sensor electrode OAE2 and the second copy sensor electrode OCPE2 may include a transparent conductive material (TCO) such as ITO or IZO. Accordingly, a decrease in the transmittance of the transmission area TA may be prevented due to the location of the light receiving element PD in the second sub-display area SDA2.

The second sensing pixel circuit PPC2 of the second sub-pixel circuit SPC2, which is connected to the second sensor electrode OAE2, may be located in the first sub-display area SDA1. The second sensor electrode OAE2 may not overlap the second sensing pixel circuit PPC2 (e.g., in the third direction DR3). The second sensor electrode OAE2 may be connected to the second thin film transistor TFT2 of the second sensing pixel circuit PPC2 through the sixth connection electrode CNE6 and the sensor bridge electrode OBRE.

The second thin film transistor TFT2 of the second sensing pixel circuit PPC2 may be any one of the first to third sensor transistors PT1 to PT3 described with reference to FIGS. 8 and 9. For example, the second thin film transistor TFT2 of the second sensing pixel circuit PPC2 may include the gate electrode PGE, the semiconductor region PACT, the first electrode PDE, and the second electrode PSE, similarly to the first sensor transistor PT1 and the second sensor transistor PT2 of FIG. 9.

In some embodiments, the sensor bridge electrode OBRE overlapping the transmission area TA may be a transparent electrode. For example, in an embodiment the sensor bridge electrode OBRE may include a transparent conductive material (TCO) such as ITO or IZO. Accordingly, a decrease in the transmittance of the transmission area TA may be prevented.

In the display device 10 according to an embodiment, light may be sensed by the light receiving element PD embedded in the sub-display area SDA. Therefore, the optical sensor is embedded in the display panel 100 itself, so that an optical sensor such as a proximity sensor or a gesture sensor may not be provided as a separate optical device 700 under the sub-display area SDA. Accordingly, the manufacturing cost may be reduced, and the module of the display device 10 may have increased compactness.

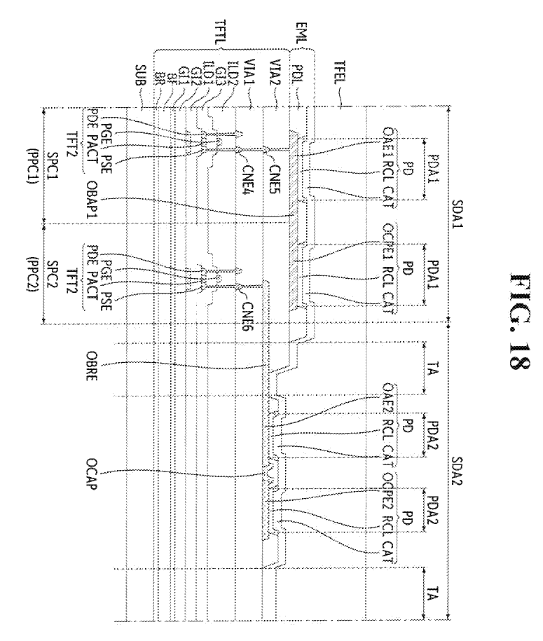

FIG. 18 is a cross-sectional view showing light receiving elements in a sub-display area of a display device according to an embodiment.

Referring to FIG. 18, the display device 10 according to an embodiment is different from the display device 10 according to embodiments described above with reference to FIGS. 10 and 15 in that the second sensor electrode OAE2, the second copy sensor electrode OCPE2, and the sensor connection pattern OCAP are located in the same layer as the sensor bridge electrode OBRE.

In an embodiment, the second via layer VIA2 may not overlap the light receiving element PD of the second sub-display area SDA2 (e.g., in a plan view). The second via layer VIA2 may be located under the light receiving element PD in the first sub-display area SDA1, but may not be located under the light receiving element PD in the second sub-display area SDA2. In an embodiment, the second sensor electrode OAE2 and the second copy sensor electrode OCPE2 of the light receiving element PD, and the sensor connection pattern OCAP in the second sub-display area SDA2 may be in direct contact with the top surface of the first via layer VIA1.

The second sensor electrode OAE2, the second copy sensor electrode OCPE2, and the sensor connection pattern OCAP may be located in the second source metal layer SDL2 (see FIG. 7) which is the same layer as the sensor bridge electrode OBRE. The second sensor electrode OAE2, the second copy sensor electrode OCPE2, and the sensor connection pattern OCAP may be positioned at a height lower than the first sensor electrode OAE1, the first copy sensor electrode OCPE1, and the first sensor bridge portion OBAP1.

In some embodiments, the second sensor electrode OAE2 may be an electrode integrated with (e.g., integrally formed therewith) the sensor bridge electrode OBRE (e.g., an integrated electrode). The second sensor electrode OAE2 and the sensor bridge electrode OBRE may constitute substantially the same electrode (e.g., one electrode connected physically) and may have substantially the same material and cross-sectional structure as each other.

In some embodiments, the second sensor electrode OAE2, the second copy sensor electrode OCPE2, and the sensor connection pattern OCAP overlapping the transmission area TA may be transparent electrodes, similarly to the bridge electrode BRE. For example, in an embodiment the second sensor electrode OAE2, the second copy sensor electrode OCPE2, and the sensor connection pattern OCAP may include a transparent conductive material (TCO) such as ITO or IZO. Accordingly, the transmittance of the transmission area TA may be increased.

In the display device 10 according to an embodiment, since the second sensor electrode OAE2, the second copy sensor electrode OCPE2, and the sensor connection pattern OCAP are located in the same layer as the bridge electrode BRE, the number of mask processes is reduced, thereby increasing process efficiency.

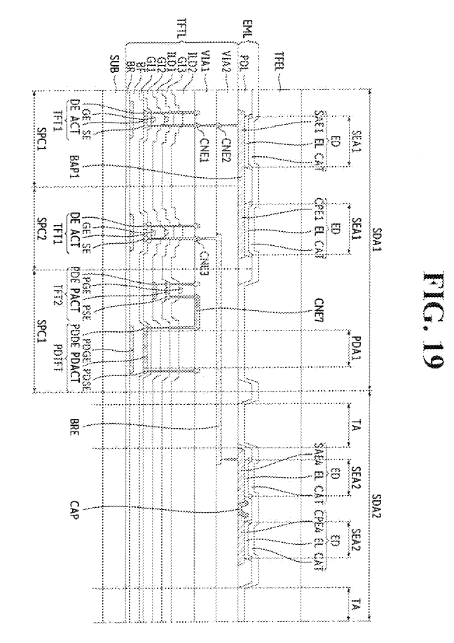

FIG. 19 is a cross-sectional view showing light emitting elements and light receiving elements in a sub-display area of a display device according to an embodiment.

Referring to FIG. 19, the display device 10 according to the present embodiment is different from the display device 10 according to the embodiments described above with reference to FIGS. 10, 15, and 18 in that the light receiving element PD is located in the circuit layer TFTL instead of the element layer EML.

In an embodiment, the light receiving element PDTFT may include a first electrode PDDE, a second electrode PDSE, a semiconductor region PDACT, and a gate electrode PDGE. In an embodiment, the first electrode PDDE, the second electrode PDSE, and the semiconductor region PDACT of the light receiving element PD may be located in the first active layer ACTL1. The gate electrode PDGE of the light receiving element PD may be located in the lower conductive layer BML. In an embodiment, the gate electrode PDGE of the light receiving element PD may have a bottom gate structure in which the gate electrode PDGE is located under the semiconductor region PDACT to increase the amount of light received in the front direction (upper direction in the third direction DR3). In an embodiment, the first electrode PDDE of the light receiving element PD may be connected to the second electrode PSE of the second thin film transistor TFT2 through a seventh connection electrode CNE7.

The light receiving element PD may be a photosensitive transistor. For example, in an embodiment the light receiving element PD may sense light by the photoconductive effect or the photogating effect of light incident on the semiconductor region PDACT.

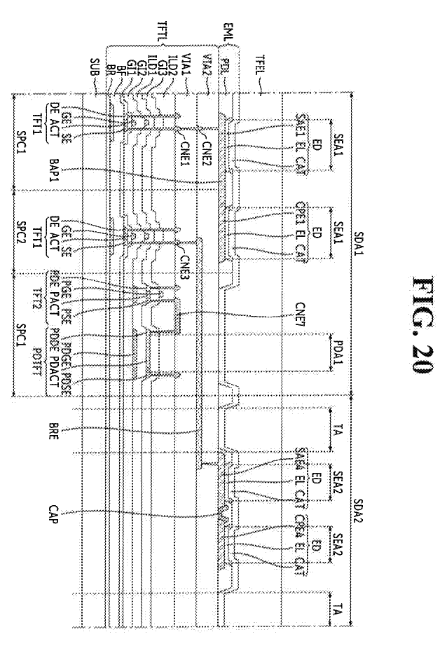

FIG. 20 is a cross-sectional view showing light emitting elements and a light receiving element in a sub-display area of a display device according to still another embodiment.

Referring to FIG. 20, the display device 10 according to an embodiment is different from the display device 10 according to an embodiment described with reference to FIG. 19 in that the layer where the light receiving layer of the light receiving element PDTFT is positioned is different.

For example, in the display device 10 according to an embodiment described with reference to FIG. 19, the light receiving layer of the light receiving element PD is located in the first active layer ACTL1, whereas in the display device 10 according to an embodiment, the light receiving layer of the light receiving element PD is located in the second active layer ACTL2.

The light receiving element PD may include a first electrode PDDE, a second electrode PDSE, a semiconductor region PDACT, and a gate electrode PDGE. The first electrode PDDE, the second electrode PDSE, and the semiconductor region PDACT of the light receiving element PD may be located in the second active layer ACTL2. The gate electrode PDGE of the light receiving element PD may be located in the second gate layer GTL2. In an embodiment, the gate electrode PDGE of the light receiving element PD may have a bottom gate structure in which the gate electrode PDGE is located under the semiconductor region PDACT to increase the amount of light received in the front direction (e.g., upper direction in the third direction DR3). In an embodiment, the first electrode PDDE of the light receiving element PD may be connected to the second electrode PSE of the second thin film transistor TFT2 through a seventh connection electrode CNE7.

The light receiving element PD may be a photosensitive transistor. For example, in an embodiment the light receiving element PD may sense light by the photoconductive effect or the photogating effect of light incident on the semiconductor region PDACT.

The display device 10 according to the above-described embodiments may be applied to various electronic devices 1. An electronic device 1 according to an embodiment may include the above-described display device 10, and may further include, in addition to the display device 10, a module or device having other additional functions.

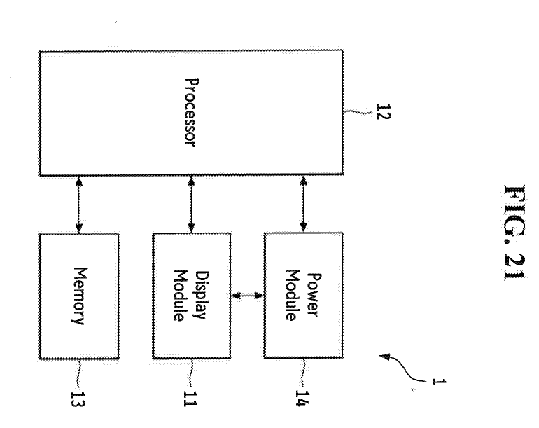

FIG. 21 is a block diagram of an electronic device according to an embodiment.

Referring to FIG. 21, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 1.

At least one of the components of the electronic device 1 described above may be included in the display device 10 according to embodiments described above. Further, some of individual modules functionally included in one module may be included in the display device 10 and some others may be provided separately from the display device 10. For example, the display device 10 may include the display module 11, and the processor 12, the memory 13, and the power module 14 may be provided in the form of other devices in the electronic device 1 other than the display device 10.

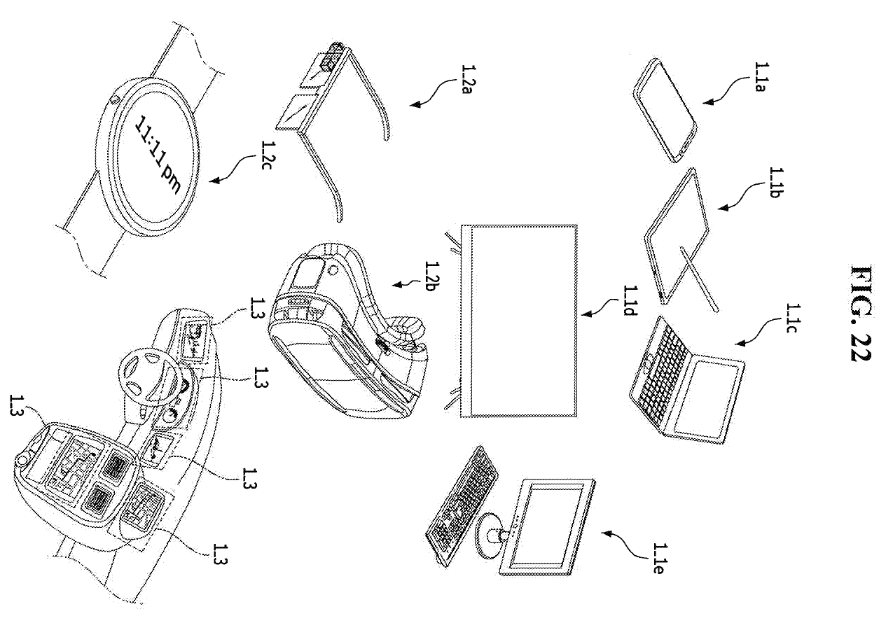

FIG. 22 is schematic views of electronic devices according to various embodiments.

Referring to FIG. 22, various electronic devices 1 to which the display device 10 according to embodiments is applied may include not only an image display electronic device 1 such as a smartphone 1_1a, a tablet personal computer 1_1b, a laptop personal computer 1_1c, a television 1_1d, and a desk monitor 1_1e, but also a wearable electronic device 1 including a display module, such as smart glasses 1_2a, a head mounted display 1_2b, a smart watch 1_2c, or the like, a vehicle electronic device 1_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and embodiments of the present disclosure are not necessarily limited thereto.

What is claimed is:

1. A display device comprising:
a first display area, a second display area surrounded by the first display area, a third display area surrounded by the second display area;
a substrate;
a circuit layer located on the substrate, and comprising a first pixel circuit located in the first display area, and a second pixel circuit, a third pixel circuit, and a first sensor circuit located in the second display area; and
an element layer located on the circuit layer,
wherein the element layer comprises:
a first pixel electrode located in the first display area, a second pixel electrode located in the second display area, a third pixel electrode located in the third display area, and a first sensor electrode located in the second display area;
a light emitting layer located on the first pixel electrode, the second pixel electrode, and the third pixel electrode;
a light receiving layer located on the first sensor electrode; and
a common electrode located on the light emitting layer and the light receiving layer,
wherein the second pixel circuit is connected to the second pixel electrode by a first connection electrode located in the second display area,
the third pixel circuit is connected to the third pixel electrode by a second connection electrode extending from the second display area to the third display area, and
the first sensor circuit is connected to the first sensor electrode by a third connection electrode located in the second display area.

2. The display device of claim 1, wherein:
the second pixel electrode comprises a first sub-pixel electrode and a first copy pixel electrode;
the first sub-pixel electrode and the first copy pixel electrode are connected by a first bridge portion; and
the first sub-pixel electrode, the first copy pixel electrode, and the first bridge portion are an integrated electrode.

3. The display device of claim 1, wherein:
the third pixel electrode comprises a second sub-pixel electrode and a second copy pixel electrode;
the second sub-pixel electrode and the second copy pixel electrode are connected by a first connection pattern; and
the first connection pattern is a separate electrode from the second sub-pixel electrode and the second copy pixel electrode.

4. The display device of claim 1, wherein the second connection electrode comprises a transparent electrode.

5. The display device of claim 1, wherein:
the first sensor electrode comprises a first sub-sensor electrode and a first copy sensor electrode;
the first sub-sensor electrode and the first copy sensor electrode are connected by a first sensor bridge portion; and
the first sub-sensor electrode, the first copy sensor electrode, and the first sensor bridge portion are an integrated electrode.

6. The display device of claim 1, wherein:
the circuit layer further comprises a second sensor circuit located in the second display area;
the element layer further comprises a second sensor electrode located in the third display area; and
the second sensor circuit is connected to the second sensor electrode by a fourth connection electrode extending from the second display area to the third display area.

7. The display device of claim 6, wherein:
the second sensor electrode comprises a second sub-sensor electrode and a second copy sensor electrode;
the second sub-sensor electrode and the second copy sensor electrode are connected by a second connection pattern; and
the second connection pattern is a separate electrode from the second sub-sensor electrode and the second copy sensor electrode.

8. The display device of claim 6, wherein the second sensor electrode and the fourth connection electrode comprise a transparent electrode.

9. The display device of claim 6, wherein the second sensor electrode is located in a same layer as the fourth connection electrode.

10. The display device of claim 9, wherein the second sensor electrode is an electrode integrated with the fourth connection electrode.

11. The display device of claim 9, wherein:
the circuit layer further comprises a via layer located below the first sensor electrode; and
the via layer is located between the first sensor electrode and the third connection electrode.

12. The display device of claim 11, wherein the via layer does not overlap the second sensor electrode in a plan view.

13. The display device of claim 9, wherein the second sensor electrode is positioned at a height lower than a height of the first sensor electrode.

14. The display device of claim 1, wherein:
a density of the first pixel electrode in the first display area is greater than a density of the second pixel electrode in the second display area; and
a density of the second pixel electrode in the second display area is greater than a density of the third pixel electrode in the third display area.

15. The display device of claim 1, further comprising:
a non-display area located outside the first display area;
a display driving circuit located in the non-display area; and
a read-out line crossing the first display area, the second display area, and the non-display area,
wherein the first sensor circuit is connected to the display driving circuit through the read-out line.

16. The display device of claim 1, further comprising a touch sensing layer located on the element layer.

17. The display device of claim 16, further comprising a color filter layer located on the touch sensing layer.

18. A display device comprising:
a first display area, a second display area surrounded by the first display area, a third display area surrounded by the second display area;
a substrate;
a circuit layer located on the substrate, and comprising a first pixel circuit located in the first display area, and a second pixel circuit, a third pixel circuit, a first sensor circuit, and a photosensitive transistor located in the second display area; and
an element layer located on the circuit layer,
wherein the element layer comprises:
a first pixel electrode located in the first display area, a second pixel electrode located in the second display area, and a third pixel electrode located in the third display area;
a light emitting layer located on the first pixel electrode, the second pixel electrode, and the third pixel electrode; and
a common electrode located on the light emitting layer,
wherein the second pixel circuit is connected to the second pixel electrode by a first connection electrode located in the second display area,
the third pixel circuit is connected to the third pixel electrode by a second connection electrode extending from the second display area to the third display area, and
the first sensor circuit is connected to the photosensitive transistor by a third connection electrode located in the second display area.

19. The display device of claim 18, wherein:
the circuit layer further comprises a first active layer in which a semiconductor region of the first to third pixel circuits is located, and a second active layer in which a semiconductor region of the first sensor circuit is located; and
a semiconductor region of the photosensitive transistor is located in at least one of the first active layer or the second active layer.

20. An electronic device comprising:
a display device displaying an image;
a processor providing an image processing signal to the display device; and
a power module supplying power to the display device and the processor,
wherein the display device comprises:
a first display area, a second display area surrounded by the first display area, a third display area surrounded by the second display area;
a substrate;
a circuit layer located on the substrate, and comprising a first pixel circuit located in the first display area, and a second pixel circuit, a third pixel circuit, and a first sensor circuit located in the second display area; and
an element layer located on the circuit layer,
wherein the element layer comprises:
a first pixel electrode located in the first display area, a second pixel electrode located in the second display area, a third pixel electrode located in the third display area, and a first sensor electrode located in the second display area;
a light emitting layer located on the first pixel electrode, the second pixel electrode, and the third pixel electrode;
a light receiving layer located on the first sensor electrode; and
a common electrode located on the light emitting layer and the light receiving layer,
wherein the second pixel circuit is connected to the second pixel electrode by a first connection electrode located in the second display area,
the third pixel circuit is connected to the third pixel electrode by a second connection electrode extending from the second display area to the third display area, and
the first sensor circuit is connected to the first sensor electrode by a third connection electrode located in the second display area.
